(19) United States
(12) Patent Application Publication
(10) Pub. No.: US 2025/0006678 A1
(43) Pub. Date: Jan. 2, 2025

(54) PACKAGING ARCHITECTURE FOR WAFER-SCALE KNOWN-GOOD-DIE HYBRID BONDING

(71) Applicant: Intel Corporation, Santa Clara, CA (US)

(72) Inventors: Omkar G. Karhade, Chandler, AZ (US); Harini Kilambi, Portland, OR (US); Kimin Jun, Portland, OR (US); Adel A. Elsherbini, Chandler, AZ (US); John Edward Zeug Matthiesen, Hillsboro, OR (US); Trianggono Widodo, Hillsboro, OR (US); Adita Das, Beaverton, OR (US); Mohit Bhatia, Chandler, AZ (US); Dimitrios Antartis, Hillsboro, OR (US); Bhaskar Jyoti Krishnatreya, Hillsboro, OR (US); Rajesh Surapaneni, Portland, OR (US); Xavier Francois Brun, Hillsboro, OR (US)

(73) Assignee: Intel Corporation, Santa Clara, CA (US)

(21) Appl. No.: 18/345,437

(22) Filed: Jun. 30, 2023

(51) Int. Cl. H01L 23/00; H01L 23/31; H01L 23/544; H01L 25/065

(52) U.S. Cl. CPC H01L 24/08; H01L 23/3107; H01L 23/544; H01L 25/0652; H01L 2223/54426; H01L 2224/08145

(57) ABSTRACT

Disclosed herein are microelectronic assemblies, related apparatuses, and methods. In some embodiments, a microelectronic assembly may include a first die in a first layer; and a second and third die in a second layer, the second layer coupled to the first layer by hybrid bond interconnects having a first pad and a second pad, wherein the first pad is coupled to a first via in the second die and the first pad is offset from the first via by a first dimension, and the second pad is coupled to a second via in the third die and the second pad is offset from the second via by a second dimension different than the first dimension. In some embodiments, the first pad is offset from the first via in a first direction and the second pad is offset from the second via in a second direction different than the first direction.

### TECHNICAL FIELD

The present disclosure relates to techniques, methods, and apparatus directed to packaging architecture for wafer-scale known-good-die (KGD) hybrid bonding.

### BACKGROUND

Electronic circuits, when commonly fabricated on a wafer of semiconductor material, such as silicon, are called integrated circuits (ICs). The wafer with such ICs is typically cut into numerous individual dies. The dies may be packaged into an IC package containing one or more dies along with other electronic components such as resistors, capacitors, and inductors. The IC package may be integrated onto an electronic system, such as a consumer electronic system, or servers, such as mainframes.

### BRIEF DESCRIPTION OF THE DRAWINGS

Embodiments will be readily understood by the following detailed description in conjunction with the accompanying drawings. To facilitate this description, like reference numerals designate like structural elements. Embodiments are illustrated by way of example, and not by way of limitation, in the figures of the accompanying drawings.

FIG. 1A is a schematic cross-sectional view of an example microelectronic assembly according to some embodiments of the present disclosure.

FIG. 1B is a schematic cross-sectional view of a portion of the example microelectronic assembly of FIG. 1A.

FIG. 1C is a schematic cross-sectional view of another example microelectronic assembly according to some embodiments of the present disclosure.

FIG. 1D is a schematic cross-sectional view of yet another example microelectronic assembly according to some embodiments of the present disclosure.

FIG. 2 is a schematic cross-sectional view of another example microelectronic assembly according to some embodiments of the present disclosure.

FIG. 3 is a schematic cross-sectional view of yet another example microelectronic assembly according to some embodiments of the present disclosure.

FIGS. 4A-4H are schematic cross-sectional views of various stages of manufacture of an example microelectronic assembly according to some embodiments of the present disclosure.

FIGS. 5A-5C are schematic cross-sectional views of various stages of manufacture of another example microelectronic assembly according to some embodiments of the present disclosure.

FIG. 6 is a cross-sectional view of a device package that includes one or more microelectronic assemblies in accordance with any of the embodiments disclosed herein.

FIG. 7 is a cross-sectional side view of a device assembly that includes one or more microelectronic assemblies in accordance with any of the embodiments disclosed herein.

FIG. 8 is a block diagram of an example computing device that includes one or more microelectronic assemblies in accordance with any of the embodiments disclosed herein.

### DETAILED DESCRIPTION

### Overview

For purposes of illustrating IC packages described herein, it is important to understand phenomena that may come into play during assembly and packaging of ICs. The following foundational information may be viewed as a basis from which the present disclosure may be properly explained. Such information is offered for purposes of explanation only and, accordingly, should not be construed in any way to limit the broad scope of the present disclosure and its potential applications.

Advances in semiconductor processing and logic design have permitted an increase in the amount of logic circuits that may be included in processors and other IC devices. As a result, many processors now have multiple cores that are monolithically integrated on a single die. Generally, these types of monolithic ICs are also described as planar since they take the form of a flat surface and are typically built on a single silicon wafer made from a monocrystalline silicon boule. The typical manufacturing process for such monolithic ICs is called a planar process, allowing photolithography, etching, heat diffusion, oxidation, and other such processes to occur on the surface of the wafer, such that active circuit elements (e.g., transistors and diodes) are formed on the planar surface of the silicon wafer.

Current technologies permit hundreds and thousands of such active circuit elements to be formed on a single die so that numerous logic circuits may be enabled thereon. In such monolithic dies, the manufacturing process must be optimized for all the circuits equally, resulting in trade-offs between different circuits. In addition, because of the limitation of having to place circuits on a planar surface, some circuits are farther apart from some others, resulting in decreased performance such as longer delays. The manufacturing yield may also be severely impacted because the entire die may have to be discarded if even one circuit is malfunctional.

One solution to overcome such negative impacts of monolithic dies is to disaggregate the circuits into smaller dies (e.g., chiplets, tiles) electrically coupled by interconnect bridges. The smaller dies are part of an assembly of interconnected dies that together form a complete IC in terms of application and/or functionality, such as a memory chip, microprocessor, microcontroller, commodity IC (e.g., chip used for repetitive processing routines, simple tasks, application specific IC, etc.), and system-on-chip (SOC). In other words, the individual dies are connected together to create the functionalities of a monolithic IC. By using separate dies, each individual die can be designed and manufactured optimally for a particular functionality. For example, a processor core that contains logic circuits might aim for performance, and thus might require a very speed-optimized layout. This has different manufacturing requirements compared to a Universal Serial Bus (USB) controller, which is built to meet certain USB standards, rather than for processing speed. Thus, by having different parts of the overall design separated into different dies, each one optimized in terms of design and manufacturing, the overall yield and cost of the combined die solution may be improved.

The connectivity between these dies is achievable in many different ways. For example, in 2.5D packaging solutions, a silicon interposer and through-silicon vias (TSVs) connect dies at silicon interconnect speed in a minimal footprint. In another example, a silicon bridge embedded under the edges of two interconnecting dies facilitates electrical coupling between them. In a three-dimensional (3D) architecture, the dies are stacked one above the other, creating a smaller footprint overall. Typically, the electrical connectivity and mechanical coupling in such 3D architecture is achieved using TSVs and high pitch solder-based bumps (e.g., C2 interconnections). The silicon bridge and the 3D stacked architecture may also be combined, which allows for top-packaged chips to communicate with other chips horizontally using the silicon bridge and vertically, using Through-Mold Vias (TMVs) which are typically larger than TSVs. Yet another packaging architecture uses hybrid bonding processes to form high-density interconnects between stacks of dies in a true 3D configuration. Hybrid bonding technology allows for much smaller interconnect pitches of less than 100 nanometers, which allows for interconnect densities of greater than 10M IOs/millimeters².

Currently, in such stacked 2.5D or 3D packaging architecture, dies are separately and individually attached to base dies to form the stack. Wafer-level processing cannot be performed because a single wafer may have more than one die that is non-functional; attaching such non-functional dies to a good die wastes resources and decreases overall manufacturing yield. Wafer to wafer hybrid bonding process can provide good bonding yields but cannot enable multiple KGD on top of a base die. Besides, wafer to wafer bonding processes cannot enable singulated die testing. Die to wafer hybrid bonding process is prone to defects due to foreign materials being introduced on bonding surface during dicing, chemical mechanical polishing, grinding, thinning, etc. Collective bonding of singulated dies on wafer can enable fast hybrid bonding but it is sensitive to defects from die singulation, thinning as well as die thickness variations. Cleaning of dies after singulation can mitigate some of the defects of die to wafer bonding, but while it is suitable in theory, in practice, it is difficult to achieve complete cleaning without damaging the bonding surfaces.

Accordingly, embodiments of the present disclosure provide a microelectronic assembly including a substrate coupled to a first layer in a stack of layers; a first die in the first layer in the stack of layers; and one or more second dies in a second layer in the stack of layers, the one or more second dies including KGDs, and the second layer coupled to the first layer by hybrid bonding having metal-to-metal bonds and fusion bonds (e.g., inorganic dielectric to inorganic dielectric bonds). The first die including a first hybrid bonding layer having a first plurality of bond pads in a dielectric material. The one or more second dies including a second hybrid bonding layer having a second plurality of bond pads in the dielectric material, where a first bond pad of the second plurality of bond pads has a first thickness and a second bond pad of the second plurality of bond pads has a second thickness different than the first thickness. In some embodiments, the second bond layer including an alignment mark.

In some embodiments, a microelectronic assembly includes a first die in a first layer; and a second die and a third die in a second layer, the second layer coupled to the first layer by hybrid bond interconnects having a first bond pad and a second bond pad, wherein the first bond pad is coupled to a first via in the second die and the first bond pad is offset from the first via by a first dimension, and the second bond pad is coupled to a second via in the third die and the second bond pad is offset from the second via by a second dimension different than the first dimension. In some embodiments, the first pad is offset from the first via in a first direction and the second pad is offset from the second via in a second direction different than the first direction.

Each of the structures, assemblies, packages, methods, devices, and systems of the present disclosure may have several innovative aspects, no single one of which is solely responsible for all the desirable attributes disclosed herein. Details of one or more implementations of the subject matter described in this specification are set forth in the description below and the accompanying drawings.

In the following detailed description, various aspects of the illustrative implementations may be described using terms commonly employed by those skilled in the art to convey the substance of their work to others skilled in the art.

The terms “circuit” and “circuitry” mean one or more passive and/or active electrical and/or electronic components that are arranged to cooperate with one another to provide a desired function. The terms also refer to analog circuitry, digital circuitry, hard wired circuitry, programmable circuitry, microcontroller circuitry and/or any other type of physical hardware electrical and/or electronic component.

The term “integrated circuit” means a circuit that is integrated into a monolithic semiconductor or analogous material.

In some embodiments, the IC dies disclosed herein may comprise substantially monocrystalline semiconductors, such as silicon or germanium, as a base material (e.g., substrate, body) on which integrated circuits are fabricated with traditional semiconductor processing methods. The semiconductor base material may include, for example, N-type or P-type materials. Dies may include, for example, a crystalline base material formed using a bulk silicon (or other bulk semiconductor material) or a silicon-on-insulator (SOI) structure. In some other embodiments, the base material of one or more of the IC dies may comprise alternate materials, which may or may not be combined with silicon, that include but are not limited to germanium, indium antimonide, lead telluride, indium arsenide, indium phosphide, gallium arsenide, indium gallium arsenide, gallium antimonide, or other combinations of group III-N, group III-V, group II-VI, or group IV materials. In yet other embodiments, the base material may comprise compound semiconductors, for example, with a first sub-lattice of at least one element from group III of the periodic table (e.g., Al, Ga, In), and a second sub-lattice of at least one element of group V of the periodic table (e.g., P, As, Sb). In yet other embodiments, the base material may comprise an intrinsic IV or III-V semiconductor material or alloy, not intentionally doped with any electrically active impurity; in alternate embodiments, nominal impurity dopant levels may be present. In still other embodiments, dies may comprise a non-crystalline material, such as polymers; for example, the base material may comprise silica-filled epoxy. In other embodiments, the base material may comprise high mobility oxide semiconductor material, such as tin oxide, antimony oxide, indium oxide, indium tin oxide, titanium oxide, zinc oxide, indium zinc oxide, indium gallium zinc oxide (IGZO), gallium oxide, titanium oxynitride, ruthenium oxide, or tungsten oxide. In general, the base material may include one or more of tin oxide, cobalt oxide, copper oxide, antimony oxide, ruthenium oxide, tungsten oxide, zinc oxide, gallium oxide, titanium oxide, indium oxide, titanium oxynitride, indium tin oxide, indium zinc oxide, nickel oxide, niobium oxide, copper peroxide, IGZO, indium telluride, molybdenite, molybdenum diselenide, tungsten diselenide, tungsten disulfide, N- or P-type amorphous or polycrystalline silicon, germanium, indium gallium arsenide, silicon germanium, gallium nitride, aluminum gallium nitride, indium phosphide, and black phosphorus, each of which may possibly be doped with one or more of gallium, indium, aluminum, fluorine, boron, phosphorus, arsenic, nitrogen, tantalum, tungsten, and magnesium, etc. Although a few examples of the material for dies are described here, any material or structure that may serve as a foundation (e.g., base material) upon which IC circuits and structures as described herein may be built falls within the spirit and scope of the present disclosure.

Unless described otherwise, IC dies described herein include one or more IC structures (or, simply, “ICs”) implementing (i.e., configured to perform) certain functionality. In one such example, the term “memory die” may be used to describe a die that includes one or more ICs implementing memory circuitry (e.g., ICs implementing one or more of memory devices, memory arrays, control logic configured to control the memory devices and arrays, etc.). In another such example, the term “compute die” may be used to describe a die that includes one or more ICs implementing logic/compute circuitry (e.g., ICs implementing one or more of I/O functions, arithmetic operations, pipelining of data, etc.).

In another example, the terms “package” and “IC package” are synonymous, as are the terms “die” and “IC die.” Note that the terms “chip,” “die,” and “IC die” are used interchangeably herein.

The term “insulating” means “electrically insulating,” the term “conducting” means “electrically conducting,” unless otherwise specified. With reference to optical signals and/or devices, components and elements that operate on or using optical signals, the term “conducting” can also mean “optically conducting.”

The terms “oxide,” “carbide,” “nitride,” etc. refer to compounds containing, respectively, oxygen, carbon, nitrogen, etc.

The term “high-k dielectric” refers to a material having a higher dielectric constant than silicon oxide, while the term “low-k dielectric” refers to a material having a lower dielectric constant than silicon oxide.

The term “insulating material” or “insulator” (also called herein as “dielectric material” or “dielectric”) refers to solid materials (and/or liquid materials that solidify after processing as described herein) that are substantially electrically nonconducting. They may include, as examples and not as limitations, organic polymers and plastics, epoxy mold compound (EMC), and inorganic materials such as ionic crystals, porcelain, glass, silicon, silicon oxide, silicon carbide, silicon carbonitride, silicon nitride, and alumina or a combination thereof. They may include dielectric materials, high polarizability materials, and/or piezoelectric materials. They may be transparent or opaque without departing from the scope of the present disclosure. Further examples of insulating materials are underfills and molds or mold-like materials used in packaging applications, including for example, materials used in organic interposers, package supports and other such components.

In various embodiments, elements associated with an IC may include, for example, transistors, diodes, power sources, resistors, capacitors, inductors, sensors, transceivers, receivers, antennas, etc. In various embodiments, elements associated with an IC may include those that are monolithically integrated within an IC, mounted on an IC, or those connected to an IC. The ICs described herein may be either analog or digital and may be used in a number of applications, such as microprocessors, optoelectronics, logic blocks, audio amplifiers, etc., depending on the components associated with the IC. The ICs described herein may be employed in a single IC die or as part of a chipset for executing one or more related functions in a computer.

In various embodiments of the present disclosure, transistors described herein may be field-effect transistors (FETs), e.g., MOSFETs. In general, a FET is a three-terminal device that includes source, drain, and gate terminals and uses electric field to control current flowing through the device. A FET typically includes a channel material, a source region and a drain regions provided in and/or over the channel material, and a gate stack that includes a gate electrode material, alternatively referred to as a “work function” material, provided over a portion of the channel material (the “channel portion”) between the source and the drain regions, and optionally, also includes a gate dielectric material between the gate electrode material and the channel material.

In a general sense, an “interconnect” refers to any element that provides a physical connection between two other elements. For example, an electrical interconnect provides electrical connectivity between two electrical components, facilitating communication of electrical signals between them; an optical interconnect provides optical connectivity between two optical components, facilitating communication of optical signals between them. As used herein, both electrical interconnects and optical interconnects are comprised in the term “interconnect.” The nature of the interconnect being described is to be understood herein with reference to the signal medium associated therewith. Thus, when used with reference to an electronic device, such as an IC that operates using electrical signals, the term “interconnect” describes any element formed of an electrically conductive material for providing electrical connectivity to one or more elements associated with the IC or/and between various such elements. In such cases, the term “interconnect” may refer to both conductive traces (also sometimes referred to as “lines,” “wires,” “metal lines” or “trenches”) and conductive vias (also sometimes referred to as “vias” or “metal vias”). Sometimes, electrically conductive traces and vias may be referred to as “conductive traces” and “conductive vias”, respectively, to highlight the fact that these elements include electrically conductive materials such as metals. Likewise, when used with reference to a device that operates on optical signals as well, such as a photonic IC (PIC), “interconnect” may also describe any element formed of a material that is optically conductive for providing optical connectivity to one or more elements associated with the PCI. In such cases, the term “interconnect” may refer to optical waveguides, including optical fiber, optical splitters, optical combiners, optical couplers, and optical vias.

The term “waveguide” refers to any structure that acts to guide the propagation of light from one location to another location typically through a substrate material such as silicon or glass. In various examples, waveguides can be formed from silicon, doped silicon, silicon nitride, glasses such as silica (e.g., silicon dioxide or SiO₂), borosilicate (e.g., 70-80 wt % SiO₂, 7-13 wt % of B₂O₃, 4-8 wt % Na₂O or K₂O, and 2-8 wt % of Al₂O₃) and so forth. Waveguides may be formed using various techniques including but not limited to forming waveguides in situ. For example, in some embodiments, waveguides may be formed in situ in glass using low temperature glass-to-glass bonding or by laser direct writing. Waveguides formed in situ may have lower loss characteristics.

The term “conductive trace” may be used to describe an electrically conductive element isolated by an insulating material. Within IC dies, such insulating material comprises interlayer low-k dielectric that is provided within the IC die. Within package substrates and printed circuit boards (PCBs) such insulating material comprises organic materials such as Ajinomoto Buildup Film (ABF), polyimides, or epoxy resin. Such conductive lines are typically arranged in several levels, or several layers, of metallization stacks.

The term “conductive via” may be used to describe an electrically conductive element that interconnects two or more conductive lines of different levels of a metallization stack. To that end, a via may be provided substantially perpendicularly to the plane of an IC die/chip or a support structure over which an IC structure is provided and may interconnect two conductive lines in adjacent levels or two conductive lines in non-adjacent levels.

The term “substrate” may be used to describe any substrate material that facilitates the packaging together of any collection of semiconductor dies and/or other electrical components such as passive electrical components. As used herein, a substrate may be formed of any material including, but not limited to, insulating materials such as resin impregnated glass fibers (e.g., PCB or Printed Wiring Boards (PWB)), glass, ceramic, silicon, silicon carbide, etc. In addition, as used herein, a substrate may refer to a package substrate that includes buildup layers (e.g., ABF layers).

The term “metallization stack” may be used to refer to a stack of one or more interconnects for providing connectivity to different circuit components of an IC die/chip and/or a substrate.

As used herein, the term “pitch” of interconnects refers to a center-to-center distance between adjacent interconnects.

In context of a stack of dies coupled to one another or in context of a die coupled to a package substrate, the term “interconnect” may also refer to, respectively, die-to-die (DTD) interconnects and die-to-substrate (DTS) interconnects. DTD interconnects may also be referred to as first-level interconnects (FLI). DTS interconnects may also be referred to as Second-Level Interconnects (SLI).

Although not specifically shown in all of the present illustrations in order to not clutter the drawings, when DTD or DTS interconnects are described, a surface of a first die may include a first set of conductive contacts, and a surface of a second die or a substrate may include a second set of conductive contacts. One or more conductive contacts of the first set may then be electrically and mechanically coupled to some of the conductive contacts of the second set by the DTD or DTS interconnects.

In some embodiments, the pitch of the DTD interconnects may be different from the pitch of the DTS interconnects, although, in other embodiments, these pitches may be substantially the same.

The DTS interconnects disclosed herein may take any suitable form. In some embodiments, a set of DTS interconnects may include solder (e.g., solder bumps or balls that are subject to a thermal reflow to form the DTS interconnects). DTS interconnects that include solder may include any appropriate solder material, such as lead/tin, tin/bismuth, eutectic tin/silver, ternary tin/silver/copper, eutectic tin/copper, tin/nickel/copper, tin/bismuth/copper, tin/indium/copper, tin/zinc/indium/bismuth, or other alloys. In some embodiments, a set of DTS interconnects may include an anisotropic conductive material, such as an anisotropic conductive film or an anisotropic conductive paste. An anisotropic conductive material may include conductive materials dispersed in a non-conductive material. In some embodiments, an anisotropic conductive material may include microscopic conductive particles embedded in a binder or a thermoset adhesive film (e.g., a thermoset biphenyl-type epoxy resin, or an acrylic-based material). In some embodiments, the conductive particles may include a polymer and/or one or more metals (e.g., nickel or gold). For example, the conductive particles may include nickel-coated gold or silver-coated copper that is in turn coated with a polymer. In another example, the conductive particles may include nickel. When an anisotropic conductive material is uncompressed, there may be no conductive pathway from one side of the material to the other. However, when the anisotropic conductive material is adequately compressed (e.g., by conductive contacts on either side of the anisotropic conductive material), the conductive materials near the region of compression may contact each other so as to form a conductive pathway from one side of the film to the other in the region of compression.

The DTD interconnects disclosed herein may take any suitable form. In some embodiments, some or all of the DTD interconnects in a microelectronic assembly or an IC package as described herein may be metal-to-metal interconnects (e.g., copper-to-copper interconnects, or plated interconnects). In such embodiments, the conductive contacts on either side of the DTD interconnect may be bonded together (e.g., under elevated pressure and/or temperature) without the use of intervening solder or an anisotropic conductive material. In some metal-to-metal interconnects, a dielectric material (e.g., silicon oxide, silicon nitride, silicon carbide) may be present between the metals bonded together (e.g., between copper pads or posts that provide the associated conductive contacts). In some embodiments, one side of a DTD interconnect may include a metal pillar (e.g., a copper pillar), and the other side of the DTD interconnect may include a metal contact (e.g., a copper contact) recessed in a dielectric. In some embodiments, a metal-to-metal interconnect (e.g., a copper-to-copper interconnect) may include a noble metal (e.g., gold) or a metal whose oxides are conductive (e.g., silver). In some embodiments, a metal-to-metal interconnect may include metal nanostructures (e.g., nanorods) that may have a reduced melting point. Metal-to-metal interconnects may be capable of reliably conducting a higher current than other types of interconnects; for example, some solder interconnects may form brittle intermetallic compounds when current flows, and the maximum current provided through such interconnects may be constrained to mitigate mechanical failure.

In some embodiments, the dies on either side of a set of DTD interconnects may be bare (e.g., unpackaged) dies.

In some embodiments, the DTD interconnects may include solder. For example, the DTD interconnects may include conductive bumps or pillars (e.g., copper bumps or pillars) attached to the respective conductive contacts by solder. In some embodiments, a thin cap of solder may be used in a metal-to-metal interconnect to accommodate planarity, and this solder may become an intermetallic compound during processing. In some embodiments, the solder used in some or all of the DTD interconnects may have a higher melting point than the solder included in some or all of the DTS interconnects. For example, when the DTD interconnects in an IC package are formed before the DTS interconnects are formed, solder-based DTD interconnects may use a higher-temperature solder (e.g., with a melting point above 200 degrees Celsius), while the DTS interconnects may use a lower-temperature solder (e.g., with a melting point below 200 degrees Celsius). In some embodiments, a higher-temperature solder may include tin; tin and gold; or tin, silver, and copper (e.g., 96.5% tin, 3% silver, and 0.5% copper). In some embodiments, a lower-temperature solder may include tin and bismuth (e.g., eutectic tin bismuth), tin, silver, bismuth, indium, indium and tin, or gallium.

In some embodiments, a set of DTD interconnects may include an anisotropic conductive material, such as any of the materials discussed above for the DTS interconnects. In some embodiments, the DTD interconnects may be used as data transfer lanes, while the DTS interconnects may be used for power and ground lines, among others.

In microelectronic assemblies or IC packages as described herein, some or all of the DTD interconnects may have a finer pitch than the DTS interconnects. In some embodiments, the DTS interconnects disclosed herein may have a pitch between about 80 microns and 300 microns, while the DTD interconnects disclosed herein may have a pitch between about 0.5 microns and 100 microns, depending on the type of the DTD interconnects. An example of silicon-level interconnect density is provided by the density of some DTD interconnects. In some embodiments, the DTD interconnects may have too fine a pitch to couple to the substrate directly (e.g., too fine to serve as DTS interconnects). The DTD interconnects may have a smaller pitch than the DTS interconnects due to the greater similarity of materials in the different dies on either side of a set of DTD interconnects than between a die and a substrate on either side of a set of DTS interconnects. In particular, the differences in the material composition of dies and substrates may result in differential expansion and contraction of the die dies and substrates due to heat generated during operation (as well as the heat applied during various manufacturing operations). To mitigate damage caused by this differential expansion and contraction (e.g., cracking, solder bridging, etc.), the DTS interconnects in any of the microelectronic assemblies or IC packages as described herein may be formed larger and farther apart than DTD interconnects, which may experience less thermal stress due to the greater material similarity of the pair of dies on either side of the DTD interconnects.

It will be recognized that one or more levels of underfill (e.g., organic polymer material such as benzotriazole, imidazole, polyimide, or epoxy) may be provided in an IC package described herein and may not be labeled in order to avoid cluttering the drawings. In various embodiments, the levels of underfill may comprise the same or different insulating materials. In some embodiments, the levels of underfill may comprise thermoset epoxies with silicon oxide particles, EMC, etc.; in some embodiments, the levels of underfill may comprise any suitable material that can perform underfill functions such as supporting the dies and reducing thermal stress on interconnects. In some embodiments, the choice of underfill material may be based on design considerations, such as form factor, size, stress, operating conditions, etc.; in other embodiments, the choice of underfill material may be based on material properties and processing conditions, such as cure temperature, glass transition temperature, viscosity and chemical resistance, among other factors; in some embodiments, the choice of underfill material may be based on both design and processing considerations.

In some embodiments, one or more levels of solder resist (e.g., epoxy liquid, liquid photoimageable polymers, dry film photoimageable polymers, acrylics, solvents) may be provided in an IC package described herein and may not be labeled or shown to avoid cluttering the drawings. Solder resist may be a liquid or dry film material including photoimageable polymers. In some embodiments, solder resist may be non-photoimageable.

The terms “substantially,” “close,” “approximately,” “near,” and “about,” generally refer to being within +/−20% of a target value (e.g., within +/−5% or 10% of a target value) based on the context of a particular value as described herein or as known in the art.

Terms indicating orientation of various elements, e.g., “coplanar,” “perpendicular,” “orthogonal,” “parallel,” or any other angle between the elements, generally refer to being within +/−5%-20% of a target value based on the context of a particular value as described herein or as known in the art.

The term “connected” means a direct connection (which may be one or more of a mechanical, electrical, and/or thermal connection) between the things that are connected, without any intermediary devices, while the term “coupled” means either a direct connection between the things that are connected, or an indirect connection through one or more passive or active intermediary devices.

The description uses the phrases “in an embodiment” or “in embodiments,” which may each refer to one or more of the same or different embodiments.

Furthermore, the terms “comprising,” “including,” “having,” and the like, as used with respect to embodiments of the present disclosure, are synonymous.

The disclosure may use perspective-based descriptions such as “above,” “below,” “top,” “bottom,” and “side”; such descriptions are used to facilitate the discussion and are not intended to restrict the application of disclosed embodiments.

The terms “over,” “under,” “between,” and “on” as used herein refer to a relative position of one material layer or component with respect to other layers or components. For example, one layer disposed over or under another layer may be directly in contact with the other layer or may have one or more intervening layers. Moreover, one layer disposed between two layers may be directly in contact with one or both of the two layers or may have one or more intervening layers. In contrast, a first layer described to be “on” a second layer refers to a layer that is in direct contact with that second layer. Similarly, unless explicitly stated otherwise, one feature disposed between two features may be in direct contact with the adjacent features or may have one or more intervening layers.

The term “dispose” as used herein refers to position, location, placement, and/or arrangement rather than to any particular method of formation.

The term “between,” when used with reference to measurement ranges, is inclusive of the ends of the measurement ranges.

For the purposes of the present disclosure, the phrase “A and/or B” means (A), (B), or (A and B). For the purposes of the present disclosure, the phrase “A, B, and/or C” means (A), (B), (C), (A and B), (A and C), (B and C), or (A, B, and C). When used herein, the notation “A/B/C” means (A), (B), and/or (C).

Although certain elements may be referred to in the singular herein, such elements may include multiple sub-elements. For example,” an electrically conductive material” may include one or more electrically conductive materials. In another example, “a dielectric material” may include one or more dielectric materials.

Unless otherwise specified, the use of the ordinal adjectives “first,” “second,” and “third,” etc., to describe a common object, merely indicate that different instances of like objects are being referred to, and are not intended to imply that the objects so described must be in a given sequence, either temporally, spatially, in ranking or in any other manner.

In the following detailed description, reference is made to the accompanying drawings that form a part hereof, and in which is shown, by way of illustration, embodiments that may be practiced. It is to be understood that other embodiments may be utilized, and structural or logical changes may be made without departing from the scope of the present disclosure. Therefore, the following detailed description is not to be taken in a limiting sense.

The accompanying drawings are not necessarily drawn to scale.

In the drawings, same reference numerals refer to the same or analogous elements/materials shown so that, unless stated otherwise, explanations of an element/material with a given reference numeral provided in context of one of the drawings are applicable to other drawings where element/materials with the same reference numerals may be illustrated. Further, the singular and plural forms of the labels may be used with reference numerals to denote a single one and multiple ones respectively of the same or analogous type, species, or class of element.

Furthermore, in the drawings, some schematic illustrations of example structures of various devices and assemblies described herein may be shown with precise right angles and straight lines, but it is to be understood that such schematic illustrations may not reflect real-life process limitations which may cause the features to not look so “ideal” when any of the structures described herein are examined using, e.g., images of suitable characterization tools such as scanning electron microscopy (SEM) images, transmission electron microscope (TEM) images, or non-contact profilometer. In such images of real structures, possible processing and/or surface defects could also be visible, e.g., surface roughness, curvature or profile deviation, pit or scratches, not-perfectly straight edges of materials, tapered vias or other openings, inadvertent rounding of corners or variations in thicknesses of different material layers, occasional screw, edge, or combination dislocations within the crystalline region(s), and/or occasional dislocation defects of single atoms or clusters of atoms. There may be other defects not listed here but that are common within the field of device fabrication and/or packaging.

Note that in the figures, various components (e.g., interconnects) are shown as aligned (e.g., at respective interfaces) merely for ease of illustration; in actuality, some or all of them may be misaligned. In addition, there may be other components, such as bond pads, landing pads, metallization, etc. present in the assembly that are not shown in the figures to prevent cluttering. Further, the figures are intended to show relative arrangements of the components within their assemblies, and, in general, such assemblies may include other components that are not illustrated (e.g., various interfacial layers or various other components related to optical functionality, electrical connectivity, or thermal mitigation). For example, in some further embodiments, the assembly as shown in the figures may include more dies along with other electrical components. Additionally, although some components of the assemblies are illustrated in the figures as being planar rectangles or formed of rectangular solids, this is simply for ease of illustration, and embodiments of these assemblies may be curved, rounded, or otherwise irregularly shaped as dictated by and sometimes inevitable due to the manufacturing processes used to fabricate various components.

In the drawings, a particular number and arrangement of structures and components are presented for illustrative purposes and any desired number or arrangement of such structures and components may be present in various embodiments.

Further, unless otherwise specified, the structures shown in the figures may take any suitable form or shape according to material properties, fabrication processes, and operating conditions.

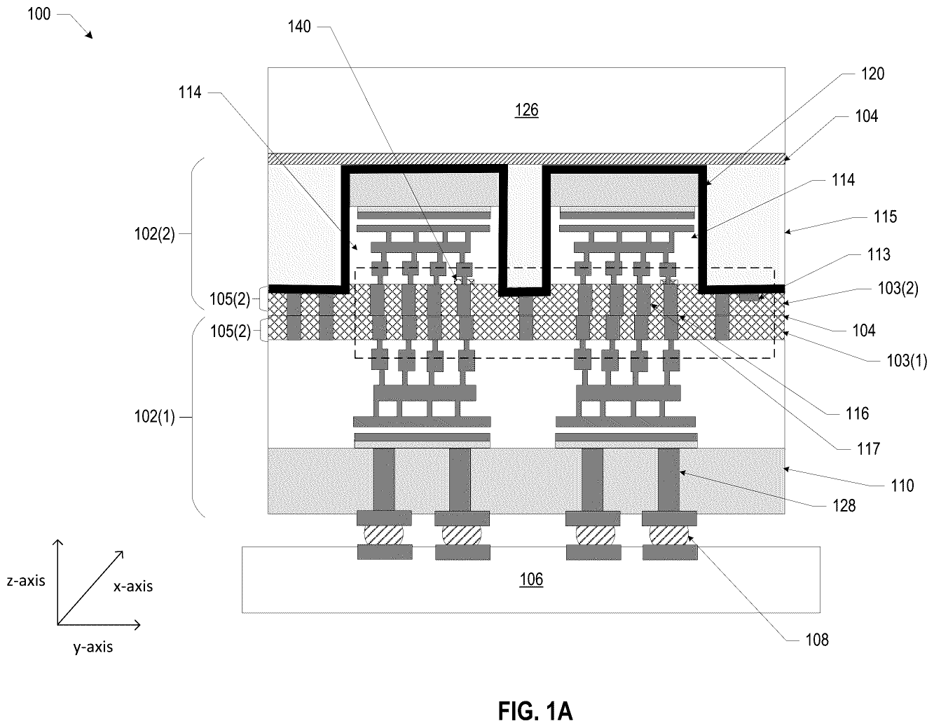

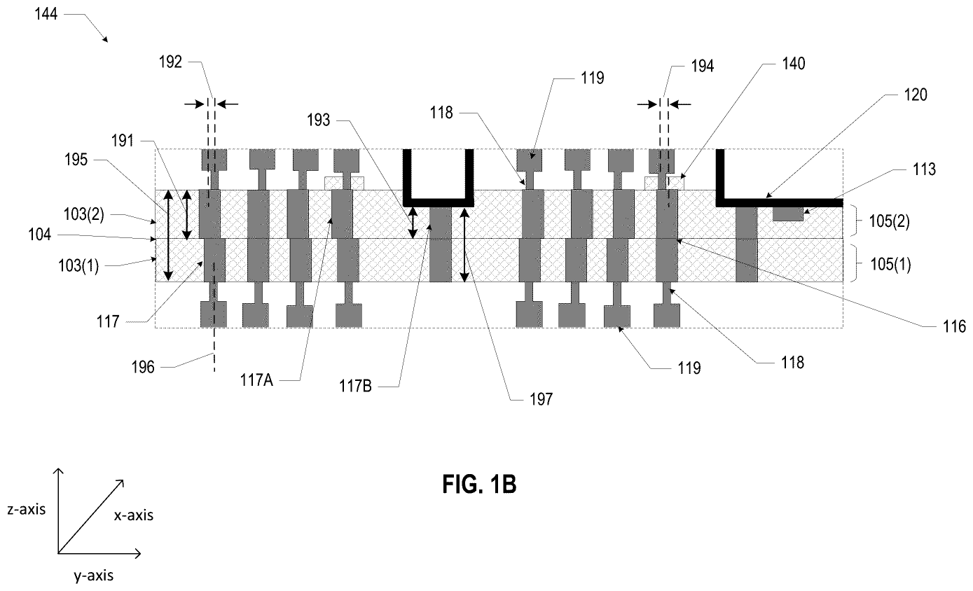

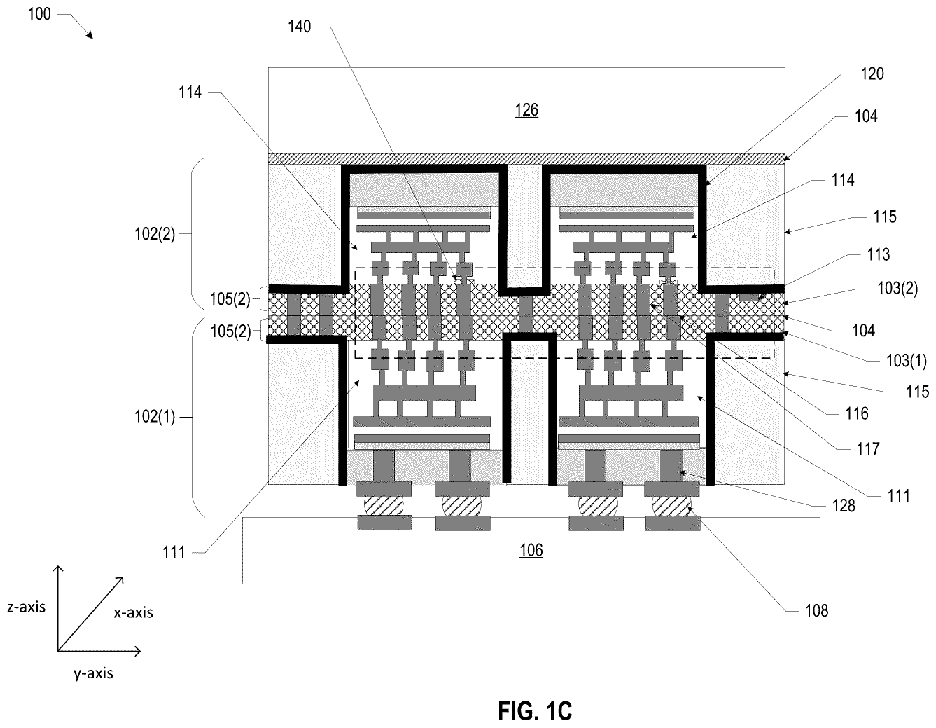

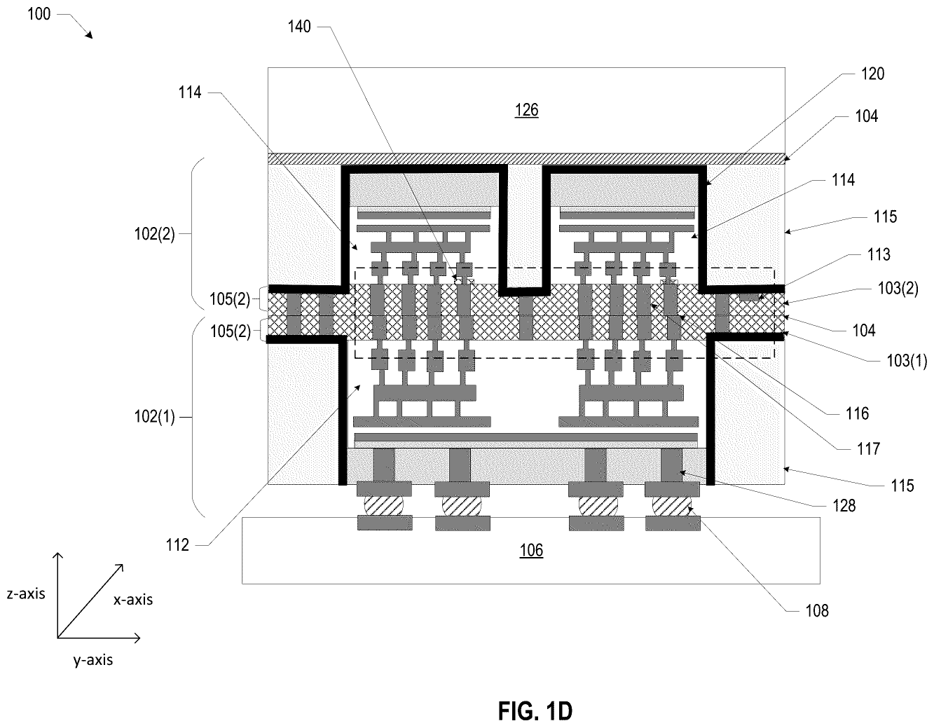

For convenience, if a collection of drawings designated with different letters are present (e.g., FIGS. 1A and 1B), such a collection may be referred to herein without the letters (e.g., as “FIG. 1”). Similarly, if a collection of reference numerals designated with different letters are present (e.g., 117A and 117B), such a collection may be referred to herein without the letters (e.g., as “117”).

Various operations may be described as multiple discrete actions or operations in turn in a manner that is most helpful in understanding the claimed subject matter. However, the order of description should not be construed as to imply that these operations are necessarily order dependent. In particular, these operations may not be performed in the order of presentation. Operations described may be performed in a different order from the described embodiment. Various additional operations may be performed, and/or described operations may be omitted in additional embodiments.

### EXAMPLE EMBODIMENTS

FIG. 1A is a schematic cross-sectional view of an example microelectronic assembly 100 according to some embodiments of the present disclosure. Microelectronic assembly 100 includes, in the embodiment shown, a stack of layers 102 (e.g., 102(1), 102(2)) coupled face-to-face by at least fusion bonds 104 (e.g., oxide-oxide bonds). In some embodiments, fusion bonds 104 may include bonds between oxides, nitrides, carbides, oxy-nitrides, oxy-carbo-nitrides, etc. The term “fusion bond” as used herein is representative of bonds between a wide variety of inorganic materials typically encountered as dielectric materials in semiconductor processing. Microelectronic assembly 100 includes a substrate 106 coupled to a particular layer (e.g., 102(1)) in the stack of layers by interconnects 108. In various embodiments, interconnects 108 may comprise DTS interconnects as described in the previous section, having a pitch between 10 microns and 2 millimeters between adjacent interconnects 108 (e.g., a pitch between about 50 microns and 300 microns). A pitch of interconnects 108 may depend on the substrate coupled to the die 110. Substrate 106 may comprise organic dielectric materials, or may be interposers having inorganic substrate materials, such as glass, ceramic, or semiconductor materials. For example, a substrate 106 may include a package substrate, a silicon interposer, a glass interposer, or a circuit board.

Layer 102(1) (or any other layer in stack of layers 102) may include one or more IC die 110 (e.g., base die). As shown in FIG. 1A, IC die 110 may include functional ICs and may further include non-functional ICs. In a general sense, IC die 110 may include an unsingulated wafer with ICs that have not passed various testing operations, such as wafer probe, burn-in, functional test, screening, etc., and that may or may not be operating within design parameters.

Layer 102(2) coupled to layer 102(1) includes one or more dies including IC dies 114. IC dies 114 include functional ICs, i.e., IC dies 114 are KGDs. In a general sense, the KGD is typically a semiconductor die with ICs that have passed various testing operations, such as wafer probe, burn-in, functional test, screening, etc., and are operating within design parameters. The KGDs are manufactured in wafer form, singulated, tested (before or after singulation) and screened before being used in microelectronic assembly 100. In various embodiments, IC dies 114 include digital logic circuits (e.g., compute, random cache memory, etc.) of a microprocessor and IC dies 110 may include other circuits (e.g., network-on-die circuit, power delivery network, physical layer interface (PHY) circuits, etc.) that enable the digital logic circuits of IC dies 114.

Dies in layer 102(2) are coupled to die in layer 102(1) by metal-metal bonds 116, in addition to fusion bonds 104. Metal-metal bonds 116 and fusion bonds 104 may together be referred to as “hybrid bonds,” created at the interface between two adjacent and contacting layers (e.g., 105(1) and 105(2)). Conductive bond pads 117 disposed in an inorganic dielectric material 103 in one of the layers (e.g., a first bond layer 105(1) on IC die 110 of layer 102(1)) may bond with conductive bond pads 117 in an inorganic dielectric material 103 disposed in the other layer (e.g., a second bond layer 105(2) on IC die 114 of layer 102(2)) to form metal-metal bonds 116; likewise, the inorganic dielectric material 103(1) (e.g., silicon and oxygen in the form of silicon oxide, silicon and nitrogen in the form of silicon nitride, silicon, oxygen, and nitrogen in the form of silicon oxynitride, etc.) in bond layer 105(1) may bond with the inorganic dielectric material 103(2) in bond layer 105(2) to form fusion bonds 104. The bonded interconnects comprise hybrid bonds, providing electrical and structural coupling between layers 102(1) and 102(2). In various embodiments, metal-metal bonds 116 may have a pitch of less than or equal to 10 microns between adjacent metal-metal bonds 116. In some embodiments, a pitch of metal-to-metal bonds 116 is between 50 nanometers and 10 microns (e.g., a pitch between 1 micron and 6 microns, or a pitch between 50 nanometers and 3 microns).

Region 144 is shown in more detail in FIG. 1B. A second bond layer 105(2) (e.g., on IC die 114 of layer 102(2)) may include first conductive bond pads 117A having a first thickness 191 (e.g., z-height) and second conductive bond pads 117B having a second thickness 193 different than the first thickness 191. A first thickness 191 may be greater than a second thickness 193. Conductive bond pads 117 of the first bond layer 105(1) (e.g., on IC die 110 of layer 102(1)) may bond with conductive bond pads 117A of the second bond layer 105(2) to form metal-metal bonds 116 having a first overall thickness 195, and conductive bond pads 117 of the first bond layer 105(1) (e.g., on IC die 110 of layer 102(1)) may bond with conductive bond pads 117A of the second bond layer 105(2) to form metal-metal bonds 116 having a second overall thickness 197, where the first overall thickness 195 is greater than the second overall thickness 197. Conductive bond pads 117 may be coupled to conductive bond vias 118 and conductive bond vias 118 may be coupled to conductive contacts 119 of IC die 110, 114. For IC die 110, individual conductive bond vias 118 may be centered 196 with individual conductive bond pads 117. For IC die 114, individual conductive bond vias 118 may be offset 192, 194 (e.g., positioned off-center) from individual conductive bond pads 117. The offset 192, 194 distances and/or directions may be different for each IC die 114. For example, as shown, the offset 192 may be smaller than the offset 194 and may be in a positive y-direction while the offset 194 may be greater and in a negative y-direction.

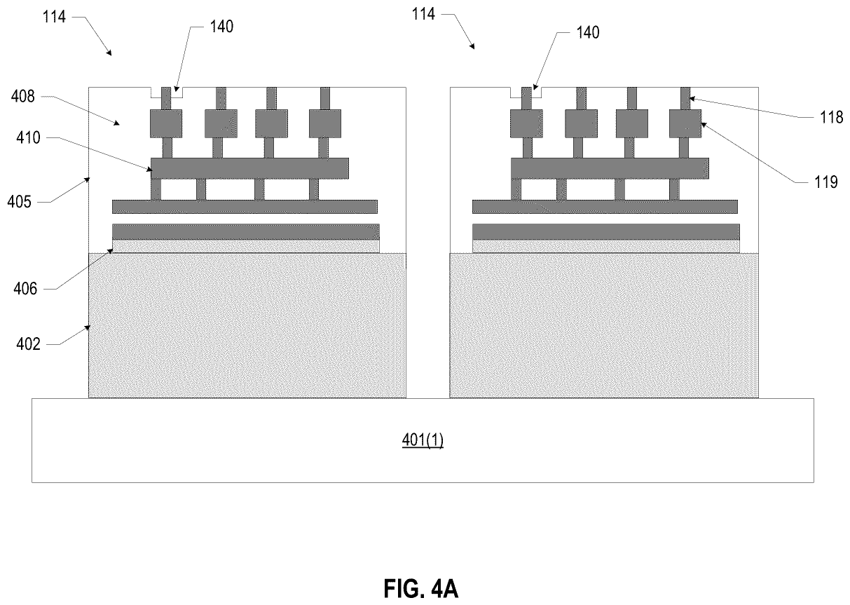

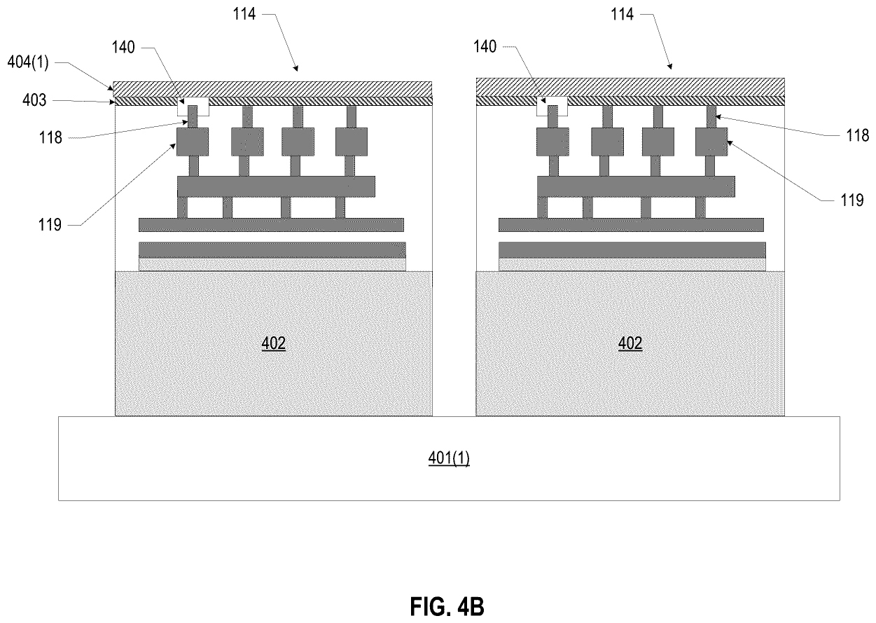

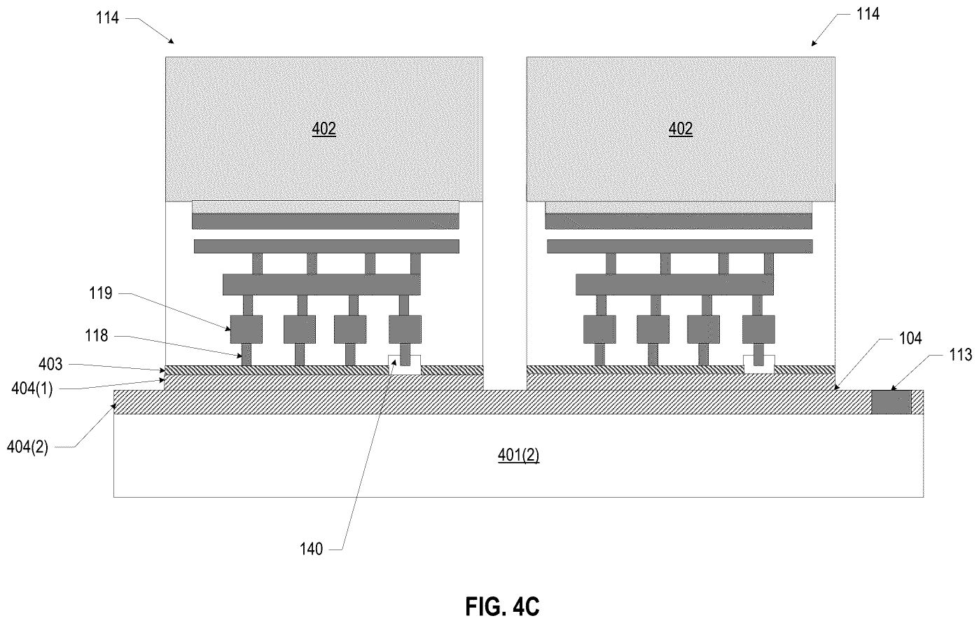

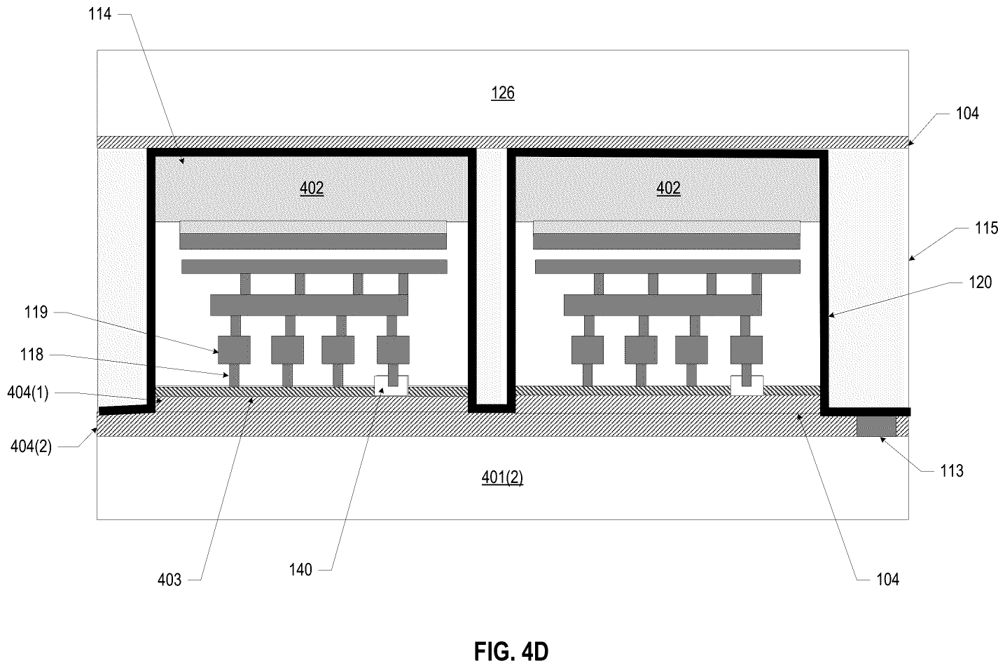

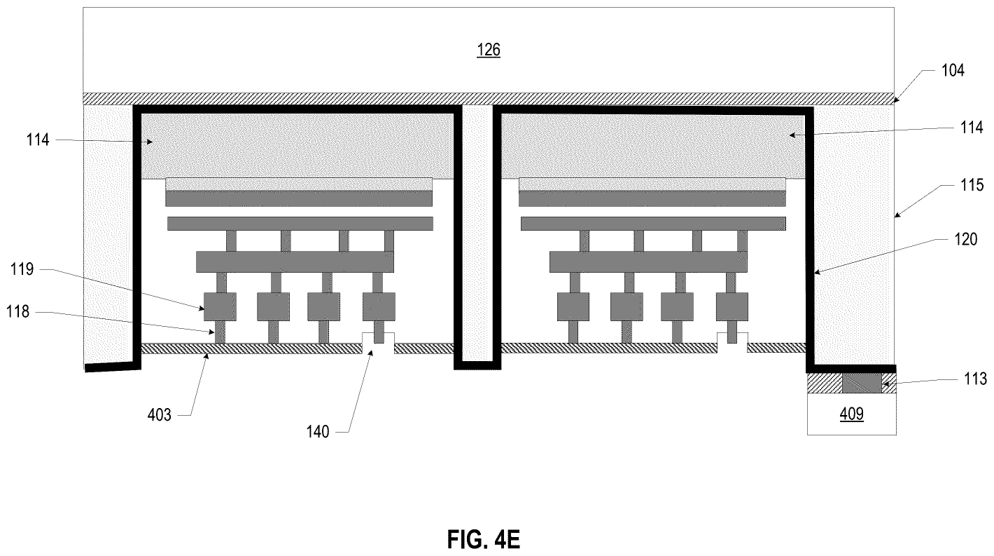

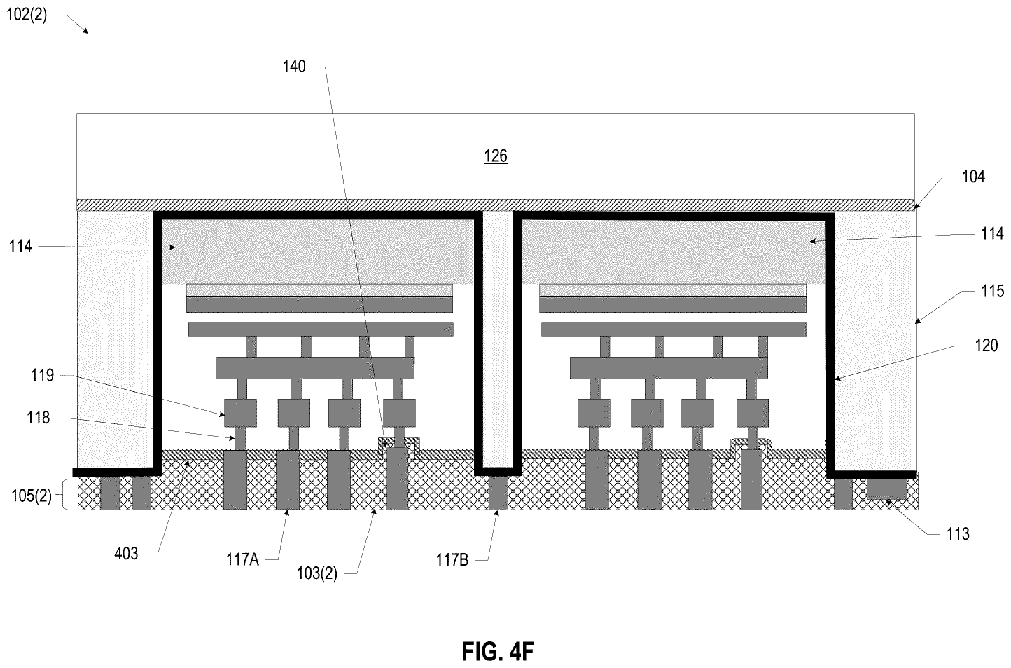

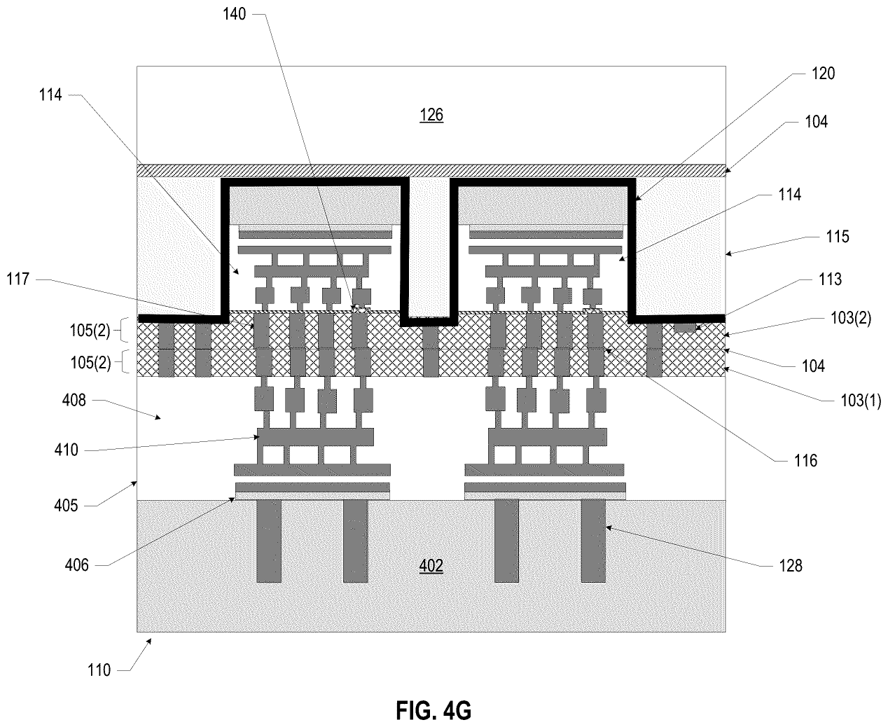

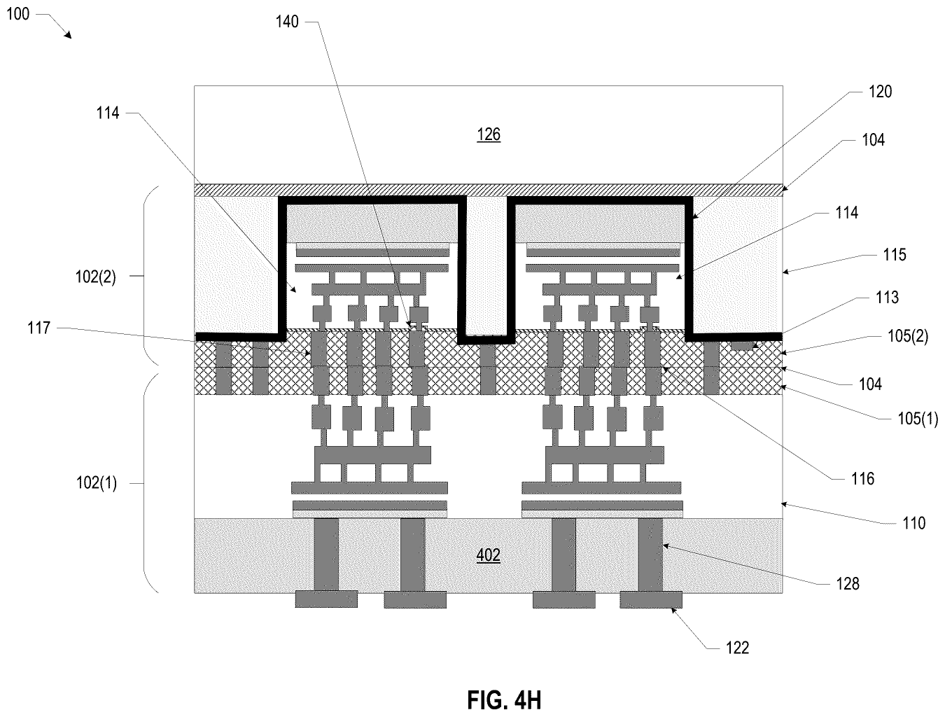

Individual ones of conductive bond vias 118 may include cavity 140. The cavity 140 may be formed during functional testing, where a conductive bond via 118 of the IC die 114 is exposed and conductively coupled to determine that the IC die 114 is a KGD. The cavity 140 may be filled with the inorganic dielectric material 103(2) of the second bond layer 105(2) when the second bond layer 105(2) is formed. In some embodiments, an etch stop layer may be formed in the cavity 140 and on the surface of IC dies 114 in layer 102(2) prior to the second bond layer 105(2) being formed on IC dies 114 (e.g., as shown in FIG. 4).

Referring back to FIG. 1A, dies in layer 102(2) may be surrounded by an encapsulating material 115. An encapsulating material 115 may include an inorganic material, such as silicon and oxygen in the form of silicon oxide, an organic material, such as resin or epoxy, or a combination of an inorganic material and an organic material, such as a mold material (e.g., an organic polymer with embedded inorganic particles, such as silicon oxide particles or aluminum oxide particles). In some embodiments, a microelectronic assembly 100 may include a liner 120 between IC die 114 and the encapsulating material 115. A liner 120 may contact and substantially cover a top surface and side surfaces of IC die 114. A liner 120 may further be between the encapsulating material 115 and the second bond layer 105(2). A liner 120 may include a passivation layer material (e.g., silicon and nitrogen in the form of silicon nitride, or silicon, carbon, and nitrogen in the form of silicon carbon nitride). A liner 120 may have a thickness (e.g., z-height at top surfaces, and a width (e.g., y-direction) and length (e.g., x-direction) at respective side surfaces) between 10 nanometers and 2 microns.

During manufacture of microelectronic assembly 100, KGDs (e.g., IC dies 114) are reconstituted on a carrier wafer and surrounded by an encapsulating material, the surface of the carrier wafer is amenable to be polished by chemical mechanical polishing (CMP) before bonding, thus providing high yields in wafer-to-wafer hybrid bonding processes. Embodiments of microelectronic assembly 100 can also facilitate aggregation of dies fabricated using different manufacturing processes (e.g., silicon nodes). For example, IC die 110 may be fabricated using a first manufacturing process, and IC dies 114 may be fabricated using different and other manufacturing processes. Further, the configuration as described herein enables wafer to wafer bonding compatible with wafer-level tools.

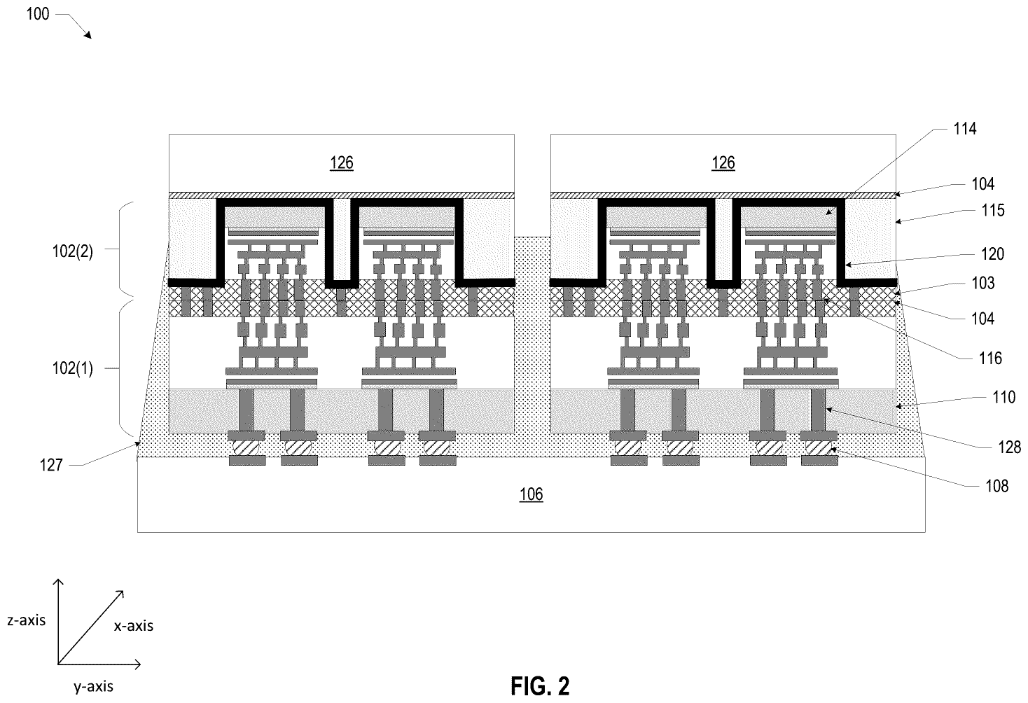

In various embodiments, a lid 126 of thermally conductive material (e.g., silicon) may be coupled to the stack of layers 102 on a side opposite to substrate 106. In some embodiments, lid 126 may be coupled to the stack of layers 102 by fusion bonds 104. In some embodiments (not shown), lid 126 may be absent. In some embodiments, one or more of the dies may include TSVs 128. For example, in the embodiment shown, IC dies 110 comprise TSVs 128. In some embodiments, a second bond layer 105(2) may include an alignment mark 113. The alignment mark 113 may assist with accurately placing IC die 114 on the carrier wafer when reconstituting IC die 114 during manufacture of microelectronic assembly 100. In some embodiments, alignment mark 113 may be absent, for example, as shown in FIG. 2.

FIG. 1C is a schematic cross-sectional view of another example microelectronic assembly 100 according to some embodiments of the present disclosure. The embodiment shown in the figure is substantially similar to the embodiment of FIG. 1A except that layer 102(1) may include one or more IC die 111. IC dies 111 include functional ICs, such that IC dies 111 are KGDs that have been reconstituted and surrounded by a liner 120 and an encapsulating material 115 similar to IC dies 114 in layer 102(2). In various embodiments, IC dies 111 include digital logic circuits (e.g., compute, random cache memory, etc.) of a microprocessor or may include other circuits (e.g., network-on-die circuit, power delivery network, physical layer interface (PHY) circuits, etc.) that enable the digital logic circuits of IC dies 114.

FIG. 1D is a schematic cross-sectional view of yet another example microelectronic assembly 100 according to some embodiments of the present disclosure. The embodiment shown in the figure is substantially similar to the embodiment of FIG. 1A except that layer 102(1) may include one or more IC die 112. Two or more IC dies 114 may be coupled to a single IC die 112. IC dies 112 include functional ICs, such that IC dies 112 are KGDs that have been reconstituted and surrounded by a liner 120 and an encapsulating material 115 similar to IC dies 114 in layer 102(2). In various embodiments, IC dies 112 may include circuits (e.g., network-on-die circuit, power delivery network, physical layer interface (PHY) circuits, etc.) that enable the digital logic circuits of IC dies 114.

FIG. 2 is a schematic cross-sectional view of another example microelectronic assembly 100 according to some embodiments of the present disclosure. The embodiment shown in the figure is substantially similar to the embodiment of FIG. 1A except that multiple stacks of layers (e.g., including layers 102(1), 102(2)) are coupled to a substrate 106. In particular, layers 102(1) in the stack of layers are coupled to the substrate 106 by interconnects 108. In various embodiments, interconnects 108 may comprise DTS interconnects as described in the previous section. In various embodiments, interconnects 108 may be surrounded by a material 127, such as an underfill material, as described in the previous section. In some embodiments, the material 127 may extend upward towards a lid 126 (e.g., along the side surfaces of the stack of layers 102(1), 102(2)).

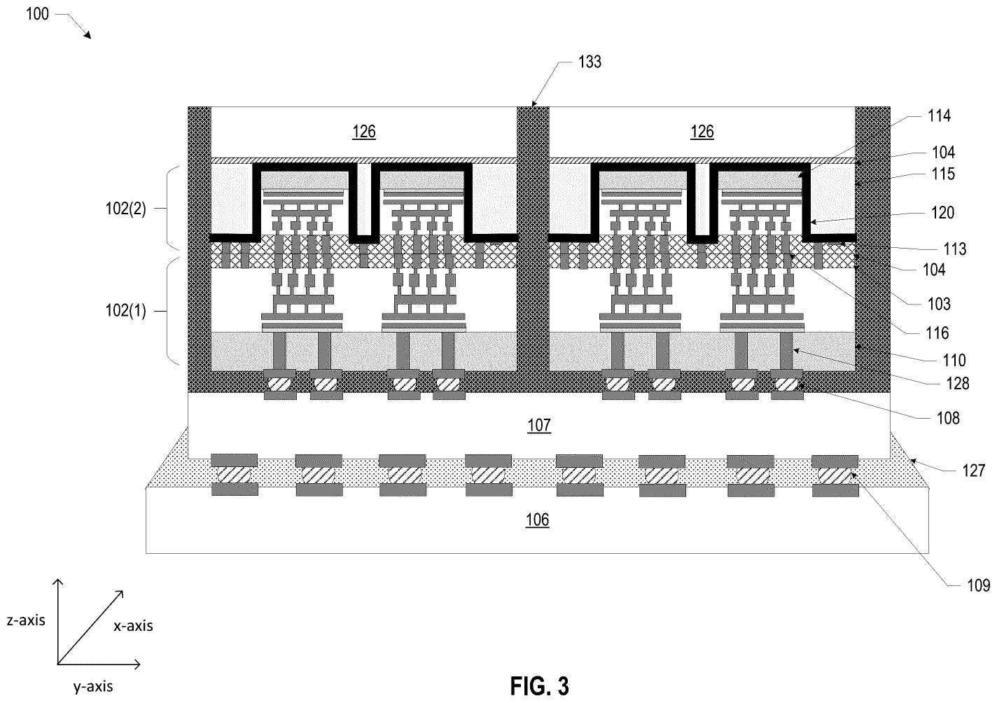

FIG. 3 is a schematic cross-sectional view of another example microelectronic assembly 100 according to some embodiments of the present disclosure. The embodiment shown in the figure is substantially similar to the embodiment of FIG. 2 except that multiple stacks of layers (e.g., including layers 102(1), 102(2)) are coupled to an interposer 107 by interconnects 108 and the interposer is coupled to a substrate 106 by interconnects 109. In various embodiments, the multiple stacks of layers (e.g., including layers 102(1), 102(2)) may be surrounded by an insulating material 133. The insulating material 133 may extend from a top surface of the interposer 107 to a top surface of the lid 126. In some embodiments, the insulating material 133 may include an inorganic dielectric (e.g., a silicon oxide material), an organic dielectric (e.g., a resin material or an epoxy material), an organic polymer with inorganic silicon oxide or aluminum oxide particles (e.g., a mold material), or multiple layers of organic dielectric and inorganic dielectric materials. In various embodiments, interconnects 108 may comprise DTS interconnects as described in the previous section. In various embodiments, interconnects 109 may comprise interconnects similar to DTS interconnects having a pitch greater than 30 microns between adjacent interconnects 109 (e.g., a pitch between about 30 microns and 2 millimeters). In various embodiments, interconnects 109 may be surrounded by a material 127, such as an underfill material, as described in the previous section.

In various embodiments, any of the features discussed with reference to any of FIGS. 1-3 herein may be combined with any other features to form a package with one or more IC dies as described herein, for example, to form a modified microelectronic assembly 100. Some such combinations are described above, but, in various embodiments, further combinations and modifications are possible.

### Example Methods

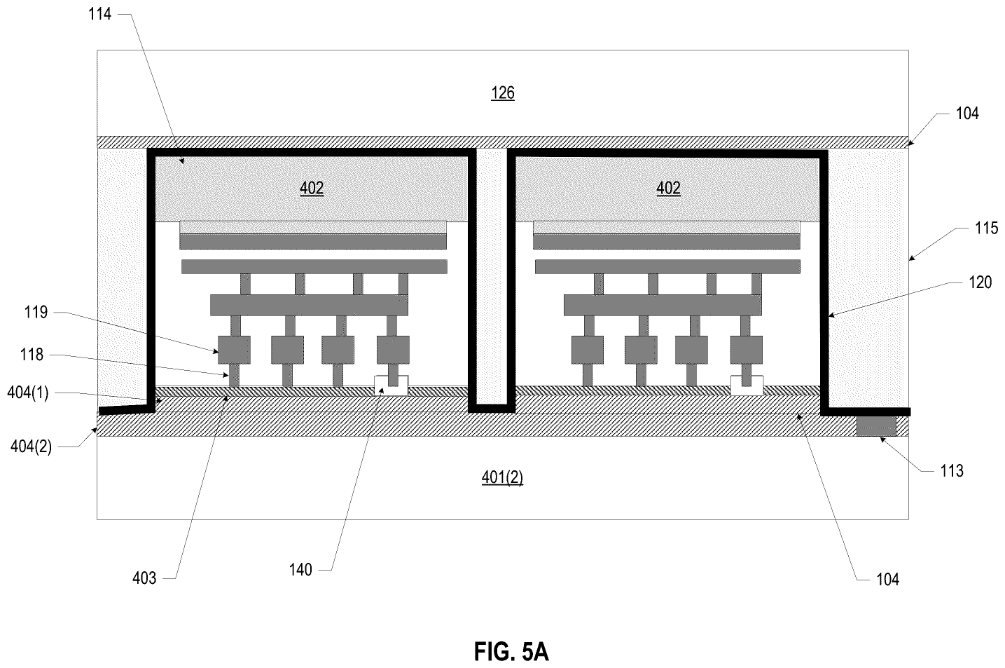

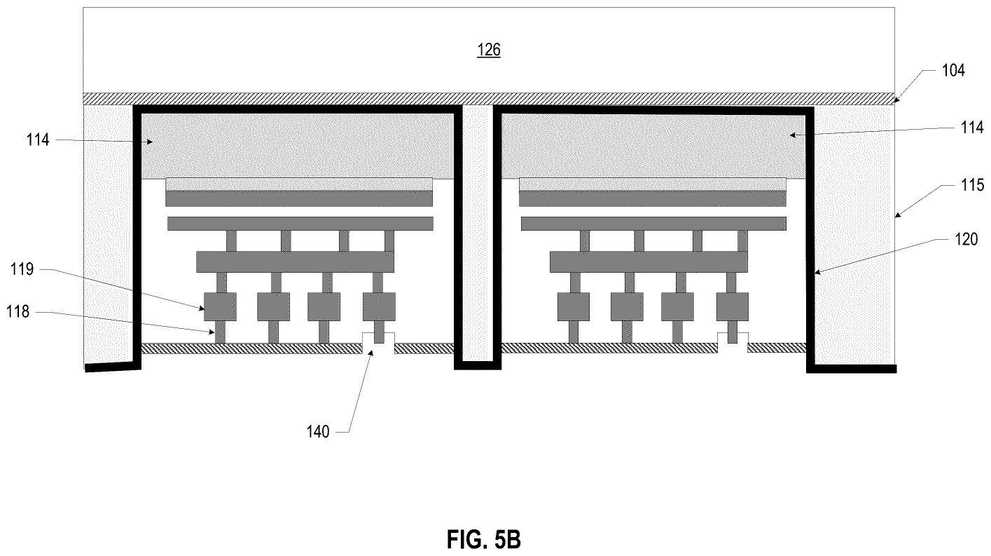

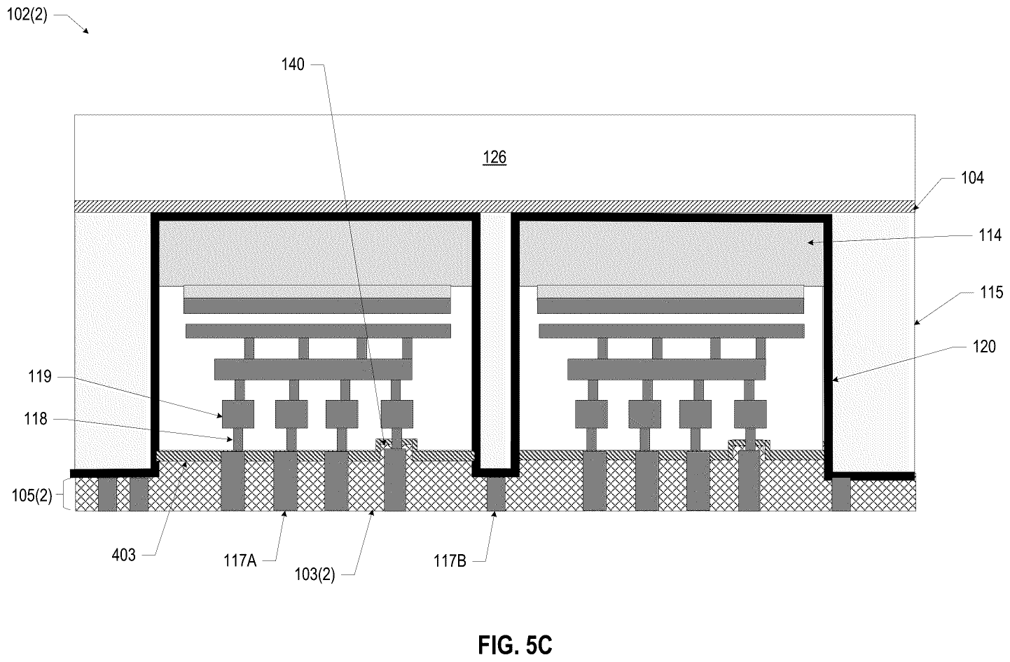

Although FIGS. 4A-4H illustrates various operations performed in a particular order, this is simply illustrative and the operations discussed herein may be reordered and/or repeated as suitable. Further, additional processes which are not illustrated may also be performed without departing from the scope of the present disclosure. Also, various ones of the operations discussed herein with respect to FIGS. 4A-4H may be modified in accordance with the present disclosure to fabricate others of microelectronic package 100 disclosed herein, for example, as described below with reference to FIGS. 5A-5C. Although various operations are illustrated in FIGS. 4A-4H once each, the operations may be repeated as often as desired. For example, one or more operations may be performed in parallel to manufacture multiple microelectronic packages substantially simultaneously. In another example, the operations may be performed in a different order to reflect the structure of a particular microelectronic package in which one or more substrates or other components as described herein may be included.

Furthermore, the operations illustrated in FIGS. 4A-4H may be combined or may include more details than described. Still further, the various operations shown and described may further include other manufacturing operations related to fabrication of other components of the microelectronic assemblies described herein, or any devices that may include the microelectronic assemblies as described herein. For example, the operations not shown in FIGS. 4A-4H may include various cleaning operations, additional surface planarization operations, operations for surface roughening, operations to include barrier and/or adhesion layers as desired, and/or operations for incorporating microelectronic assemblies as described herein in, or with, an IC component, a computing device, or any desired structure or device.

FIGS. 4A-4H are schematic cross-sectional views of various stages of manufacture of an example microelectronic assembly 100 according to some embodiments of the present disclosure. FIG. 4A illustrates an assembly subsequent to a plurality of IC dies 114 being attached to a first carrier 401(1). Each of IC dies 114 including a substrate 402 and a metallization stack 405 with an active region 406 between substrate 402 and metallization stack 405. Metallization stack 405 comprises a plurality of layers of interlayer dielectric (ILD) material 408 and conductive pathways 410 through ILD material 408. Metallization stack 405 may include conductive contacts 119 and conductive bond vias 118. Various active components such as diodes and transistors are in active region 406 between substrate 402 and metallization stack 405. In some embodiments (not shown) IC dies 114 may also include TSVs. IC die 114 may include a cavity 140 around a conductive bond via 118 to enable testing operations to be performed. A first carrier 401(1) may include any suitable material for providing mechanical stability during manufacturing operations, and in some embodiments, may include a semiconductor wafer (e.g., a silicon wafer) or glass (e.g., a glass panel). IC dies 114 may be placed on the first carrier 401(1) using any suitable process and may be attached to the first carrier 401(1) using any suitable technique, for example, a temporary adhesive.

FIG. 4B illustrates an assembly subsequent to forming a nitride layer 403 on a top surface of the assembly of FIG. 4A and forming an oxide layer 404(1) on the nitride layer 403. The nitride layer 403 may function as an etch stop layer (e.g., as described below with reference to FIG. 4E) and may include any suitable material, such as silicon and nitrogen (e.g., in the form of silicon nitride) or silicon, carbon, and nitrogen (e.g., in the form of silicon carbon nitride). The oxide layer 404(1) may include any suitable material, such as silicon and oxygen (e.g., in the form of silicon oxide).

FIG. 4C illustrates an assembly subsequent to removing IC dies 114 from the first carrier 401(1) and reconstituting IC dies 114 on a second carrier 401(2). IC dies 114 are KGDs, that is, they have passed various testing operations so that it is known that they have no substantial defects, and they conform to design specifications. The second carrier 401(2) may be coated with an oxide layer 404(2) that forms fusion bonds 104 with the oxide layer 404(1) on the IC dies 114. The assembly may be subject to high temperature (and/or pressure) such that oxide layers 404(1), 404(2) bond to form fusion bonds 104. The second carrier 401(2) may further include an alignment mark 113 to assist with positioning IC dies 114 accurately.

FIG. 4D illustrates an assembly subsequent to thinning the substrate 402 of IC dies 114, forming a liner 120 on a top surface of the assembly of FIG. 4C, depositing an encapsulating material 115 on the liner 120 and around IC dies 114, and attaching a lid 126 to a top surface of the encapsulating material 115 by fusion bonds 104. A liner 120 may include any suitable material, as described above with reference to FIG. 1. A liner 120 may be deposited using any suitable technique, such as a Plasma Enhanced Chemical Vapor Deposition (PECVD) process or an atomic layer deposition (ALD) process. The encapsulating material 115 may include any suitable material, as described above with reference to FIG. 1, and may be deposited using any suitable technique, such as a PECVD process. In some embodiments, the encapsulating material 115 may be deposited on and over a top surface of IC dies 114 and planarized to remove excess material, for example, by mechanical grinding and/or CMP.

FIG. 4E illustrates an assembly subsequent to removing the second carrier 401(2), applying a photoresist material 409 on the alignment mark 113, and removing the oxide layer 404(e.g., 404(1), 404(2)) from a bottom surface of the assembly. The oxide layer 404 may be removed using any suitable technique, such as a selective dry or wet etch to expose the nitride layer 403 and portions of the liner 120. The alignment mark 113 may not be removed (e.g., protected by the photoresist material 409). In some embodiments, the alignment mark 113 may be removed, as described below with reference to FIG. 5.

FIG. 4F illustrates an assembly (e.g., layer 102(2)) subsequent to depositing a nitride layer 403 in the cavity 140, and forming a bond layer 105(2) by depositing an inorganic dielectric material 103(2) in the cavity and on a bottom surface of the assembly of FIG. 4E and forming conductive bond pads 117. The inorganic dielectric material 103(2) may be deposited and the conductive bond pads 117 may be formed using any suitable technique, such as using a lithography process or a damascene process. Conductive bond pads 117 may include conductive bond pads 117A, 117B having different thicknesses, as described above with reference to FIG. 1B. The alignment mark 113 may assist with aligning conductive bond pads 117 with conductive bond vias 118. Conductive bond pads 117 may be offset from conductive bond vias 118 (e.g., as described above with reference to FIG. 1B). the bottom surface of the assembly may be subjected to cleaning operations.

FIG. 4G illustrates an assembly subsequent to coupling the assembly of FIG. 4F and an IC die 110. The bond layer 105(2) of layer 102(2) may be placed in contact with the bond layer 105(1) of IC die 110 to form fusion bonds 104 and metal-metal bonds 116 between IC die 110 and IC dies 114. The assembly of FIG. 4G may be subjected to high temperature and pressure to form metal-to-metal bonds 116. IC die 110 may include a substrate 402, a metallization stack 405 with a plurality of layers of interlayer dielectric (ILD) material 408 and conductive pathways 410 through ILD material 408, and an active region 406 between substrate 402 and metallization stack 405 (e.g., similar to IC die 114 in FIG. 4A). IC die 110 may further include TSVs 128 in the substrate 402.

FIG. 4H illustrates an assembly subsequent to exposing TSVs 128 in the substrate 402 of IC die 110 and forming conductive contacts 122 on a bottom surface of the assembly. The material of the substrate may be removed using any suitable technique, including grinding and/or CMP, to expose the TSVs 128. Conductive contacts 122 may be formed using any suitable technique, including plating, on the exposed surfaces of the TSVs 128. The assembly of FIG. 4H may be a microelectronic assembly 100, as shown. If multiple assemblies are manufactured together, the assemblies may be singulated. Further manufacturing operations may be performed on the microelectronic assembly 100 of FIG. 4H to form other microelectronic assembly 100; for example, the solder may be plated on the conductive contacts 122 and used to couple the microelectronic assembly 100 of FIG. 4H to a substrate 106 via interconnects 108, similar to the microelectronic assembly 100 of FIG. 1A.

FIGS. 5A-5C are schematic cross-sectional views of various stages of manufacture of an example microelectronic assembly 100 according to some embodiments of the present disclosure. FIG. 5A illustrates an assembly formed by various operations, for example, the operations as described above with reference to FIGS. 4A-4D.

FIG. 5B illustrates an assembly subsequent to removing the second carrier 401(2), and removing the oxide layer 404(e.g., 404(1), 404(2)) from a bottom surface of the assembly. The oxide layer 404 may be removed using any suitable technique, such as a selective dry or wet etch to expose the nitride layer 403 and portions of the liner 120. As shown in FIG. 5B, the alignment mark 113 is removed with the oxide layer 404.

FIG. 5C illustrates an assembly (e.g., layer 102(2)) subsequent to depositing a nitride layer 403 in the cavity 140, and forming a bond layer 105(2) by depositing an inorganic dielectric material 103(2) in the cavity and on a bottom surface of the assembly of FIG. 5B and forming conductive bond pads 117. The inorganic dielectric material 103(2) may be deposited and the conductive bond pads 117 may be formed using any suitable technique, such as using a lithography process or a damascene process. Conductive bond pads 117 may include conductive bond pads 117A, 117B having different thicknesses, as described above with reference to FIG. 1B. Conductive bond pads 117 may be offset from conductive bond vias 118 (e.g., as described above with reference to FIG. 1B). the bottom surface of the assembly may be subjected to cleaning operations. Further operations may be performed on the assembly of FIG. 5C, for example, operations described above with reference to FIGS. 4G and 4H, to form microelectronic assembly 100.

### Example Devices and Components

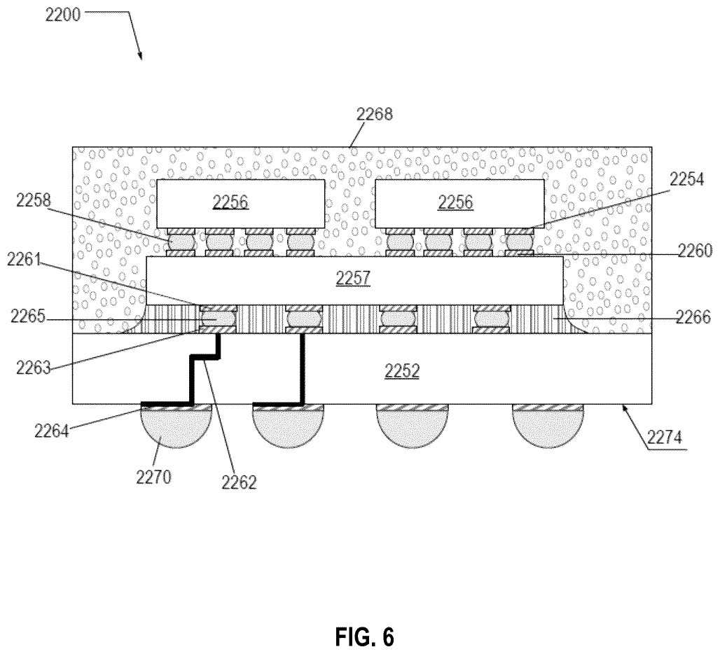

The microelectronic assemblies disclosed herein, e.g., any of the embodiments shown in FIGS. 1-5 or any further embodiments described herein, may be included in any suitable electronic component. FIGS. 6-8 illustrate various examples of packages, assemblies, and devices that may be used with or include any of the IC packages as disclosed herein.

FIG. 6 is a side, cross-sectional view of an example IC package 2200 that may include a microelectronic assembly 100 in accordance with any of the embodiments disclosed herein. In some embodiments, the IC package 2200 may be a SiP.

As shown in the figure, package substrate 2252 may be formed of an insulator (e.g., a ceramic, a buildup film, an epoxy film having filler particles therein, etc.), and may have conductive pathways extending through the insulator between first face 2272 and second face 2274, or between different locations on first face 2272, and/or between different locations on second face 2274. These conductive pathways may take the form of any of the interconnect structures comprising lines and/or vias.

Package substrate 2252 may include conductive contacts 2263 that are coupled to conductive pathway 2262 through package substrate 2252, allowing circuitry within dies 2256 and/or interposer 2257 to electrically couple to various ones of conductive contacts 2264(or to other devices included in package substrate 2252, not shown).

IC package 2200 may include interposer 2257 coupled to package substrate 2252 via conductive contacts 2261 of interposer 2257, first-level interconnects 2265, and conductive contacts 2263 of package substrate 2252. First-level interconnects 2265 illustrated in the figure are solder bumps, but any suitable first-level interconnects 2265 may be used, such as solder bumps, solder posts, or bond wires.

IC package 2200 may include one or more dies 2256 coupled to interposer 2257 via conductive contacts 2254 of dies 2256, first-level interconnects 2258, and conductive contacts 2260 of interposer 2257. Conductive contacts 2260 may be coupled to conductive pathways (not shown) through interposer 2257, allowing circuitry within dies 2256 to electrically couple to various ones of conductive contacts 2261(or to other devices included in interposer 2257, not shown). First-level interconnects 2258 illustrated in the figure are solder bumps, but any suitable first-level interconnects 2258 may be used, such as solder bumps, solder posts, or bond wires. As used herein, a “conductive contact” may refer to a portion of electrically conductive material (e.g., metal) serving as an interface between different components; conductive contacts may be recessed in, flush with, or extending away from a surface of a component, and may take any suitable form (e.g., a conductive pad or socket).

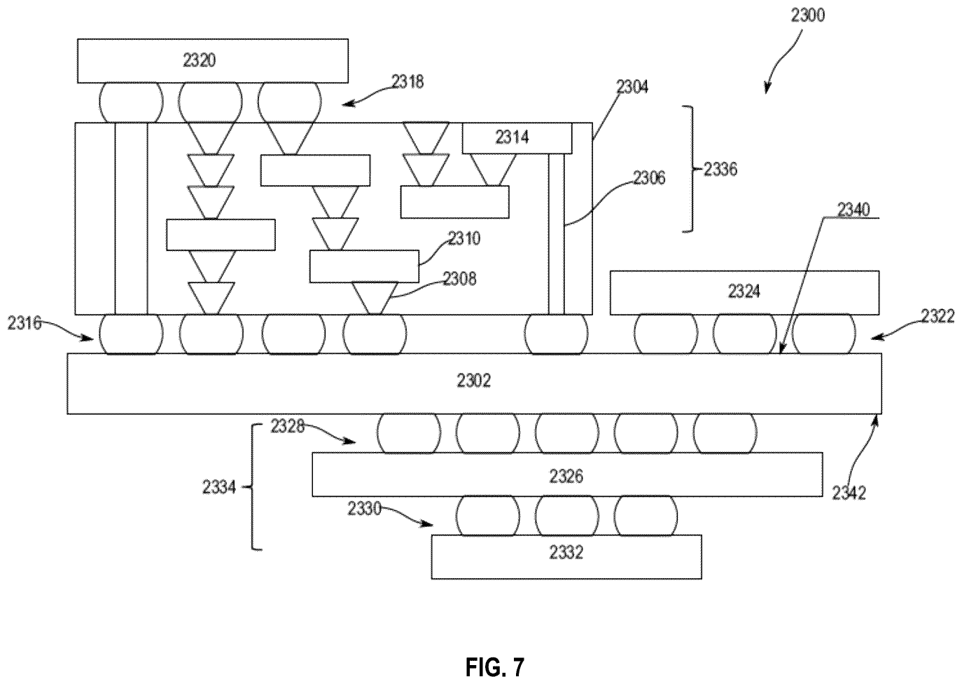

In some embodiments, underfill material 2266 may be disposed between package substrate 2252 and interposer 2257 around first-level interconnects 2265, and mold 2268 may be disposed around dies 2256 and interposer 2257 and in contact with package substrate 2252. In some embodiments, underfill material 2266 may be the same as mold 2268. Example materials that may be used for underfill material 2266 and mold 2268 are epoxies as suitable. Second-level interconnects 2270 may be coupled to conductive contacts 2264. Second-level interconnects 2270 illustrated in the figure are solder balls (e.g., for a ball grid array (BGA) arrangement), but any suitable second-level interconnects 2270 may be used (e.g., pins in a pin grid array arrangement or lands in a land grid array arrangement). Second-level interconnects 2270 may be used to couple IC package 2200 to another component, such as a circuit board (e.g., a motherboard), an interposer, or another IC package, as known in the art and as discussed below with reference to FIG. 7.

In various embodiments, any of dies 2256 may be microelectronic assembly 100 as described herein. In embodiments in which IC package 2200 includes multiple dies 2256, IC package 2200 may be referred to as a multi-chip package (MCP). Dies 2256 may include circuitry to perform any desired functionality. For example, besides one or more of dies 2256 being microelectronic assembly 100 as described herein, one or more of dies 2256 may be logic dies (e.g., silicon-based dies), one or more of dies 2256 may be memory dies (e.g., HBM), etc. In some embodiments, any of dies 2256 may be implemented as discussed with reference to any of the previous figures. In some embodiments, at least some of dies 2256 may not include implementations as described herein.

Although IC package 2200 illustrated in the figure is a flip-chip package, other package architectures may be used. For example, IC package 2200 may be a BGA package, such as an embedded wafer-level ball grid array (eWLB) package. In another example, IC package 2200 may be a wafer-level chip scale package (WLCSP) or a panel fan-out (FO) package. Although two dies 2256 are illustrated in IC package 2200, IC package 2200 may include any desired number of dies 2256. IC package 2200 may include additional passive components, such as surface-mount resistors, capacitors, and inductors disposed over first face 2272 or second face 2274 of package substrate 2252, or on either face of interposer 2257. More generally, IC package 2200 may include any other active or passive components known in the art.

In some embodiments, no interposer 2257 may be included in IC package 2200; instead, dies 2256 may be coupled directly to conductive contacts 2263 at first face 2272 by first-level interconnects 2265.

FIG. 7 is a cross-sectional side view of an IC device assembly 2300 that may include components having one or more microelectronic assembly 100 in accordance with any of the embodiments disclosed herein. IC device assembly 2300 includes a number of components disposed over a circuit board 2302 (which may be, e.g., a motherboard). IC device assembly 2300 includes components disposed over a first face 2340 of circuit board 2302 and an opposing second face 2342 of circuit board 2302; generally, components may be disposed over one or both faces 2340 and 2342. In particular, any suitable ones of the components of IC device assembly 2300 may include any of the one or more microelectronic assembly 100 in accordance with any of the embodiments disclosed herein; e.g., any of the IC packages discussed below with reference to IC device assembly 2300 may take the form of any of the embodiments of IC package 2200 discussed above with reference to FIG. 6.

In some embodiments, circuit board 2302 may be a PCB including multiple metal layers separated from one another by layers of insulator and interconnected by electrically conductive vias. Any one or more of the metal layers may be formed in a desired circuit pattern to route electrical signals (optionally in conjunction with other metal layers) between the components coupled to circuit board 2302. In other embodiments, circuit board 2302 may be a non-PCB package substrate.

As illustrated in the figure, in some embodiments, IC device assembly 2300 may include a package-on-interposer structure 2336 coupled to first face 2340 of circuit board 2302 by coupling components 2316. Coupling components 2316 may electrically and mechanically couple package-on-interposer structure 2336 to circuit board 2302, and may include solder balls (as shown), male and female portions of a socket, an adhesive, an underfill material, and/or any other suitable electrical and/or mechanical coupling structure.

Package-on-interposer structure 2336 may include IC package 2320 coupled to interposer 2304 by coupling components 2318. Coupling components 2318 may take any suitable form depending on desired functionalities, such as the forms discussed above with reference to coupling components 2316. In some embodiments, IC package 2320 may be or include IC package 2200, e.g., as described above with reference to FIG. 6. In some embodiments, IC package 2320 may include at least one microelectronic assembly 100 as described herein. Microelectronic assembly 100 is not specifically shown in the figure in order to not clutter the drawing.

Although a single IC package 2320 is shown in the figure, multiple IC packages may be coupled to interposer 2304; indeed, additional interposers may be coupled to interposer 2304. Interposer 2304 may provide an intervening package substrate used to bridge circuit board 2302 and IC package 2320. Generally, interposer 2304 may redistribute a connection to a wider pitch or reroute a connection to a different connection. For example, interposer 2304 may couple IC package 2320 to a BGA of coupling components 2316 for coupling to circuit board 2302.

In the embodiment illustrated in the figure, IC package 2320 and circuit board 2302 are attached to opposing sides of interposer 2304. In other embodiments, IC package 2320 and circuit board 2302 may be attached to a same side of interposer 2304. In some embodiments, three or more components may be interconnected by way of interposer 2304.

Interposer 2304 may be formed of an epoxy resin, a fiberglass-reinforced epoxy resin, a ceramic material, or a polymer material such as polyimide. In some implementations, interposer 2304 may be formed of alternate rigid or flexible materials that may include the same materials described above for use in a semiconductor substrate, such as silicon, germanium, and other group III-V and group IV materials. Interposer 2304 may include metal interconnects 2308 and vias 2310, including but not limited to TSVs 2306. Interposer 2304 may further include embedded devices 2314, including both passive and active devices. Such devices may include, but are not limited to, capacitors, decoupling capacitors, resistors, inductors, fuses, diodes, transformers, sensors, ESD devices, and memory devices. More complex devices such as radio frequency (RF) devices, power amplifiers, power management devices, antennas, arrays, sensors, and microelectromechanical systems (MEMS) devices may also be formed on interposer 2304. Package-on-interposer structure 2336 may take the form of any of the package-on-interposer structures known in the art.

In some embodiments, IC device assembly 2300 may include an IC package 2324 coupled to first face 2340 of circuit board 2302 by coupling components 2322. Coupling components 2322 may take the form of any of the embodiments discussed above with reference to coupling components 2316, and IC package 2324 may take the form of any of the embodiments discussed above with reference to IC package 2320.

In some embodiments, IC device assembly 2300 may include a package-on-package structure 2334 coupled to second face 2342 of circuit board 2302 by coupling components 2328. Package-on-package structure 2334 may include an IC package 2326 and an IC package 2332 coupled together by coupling components 2330 such that IC package 2326 is disposed between circuit board 2302 and IC package 2332. Coupling components 2328 and 2330 may take the form of any of the embodiments of coupling components 2316 discussed above, and IC packages 2326 and/or 2332 may take the form of any of the embodiments of IC package 2320 discussed above. Package-on-package structure 2334 may be configured in accordance with any of the package-on-package structures known in the art.

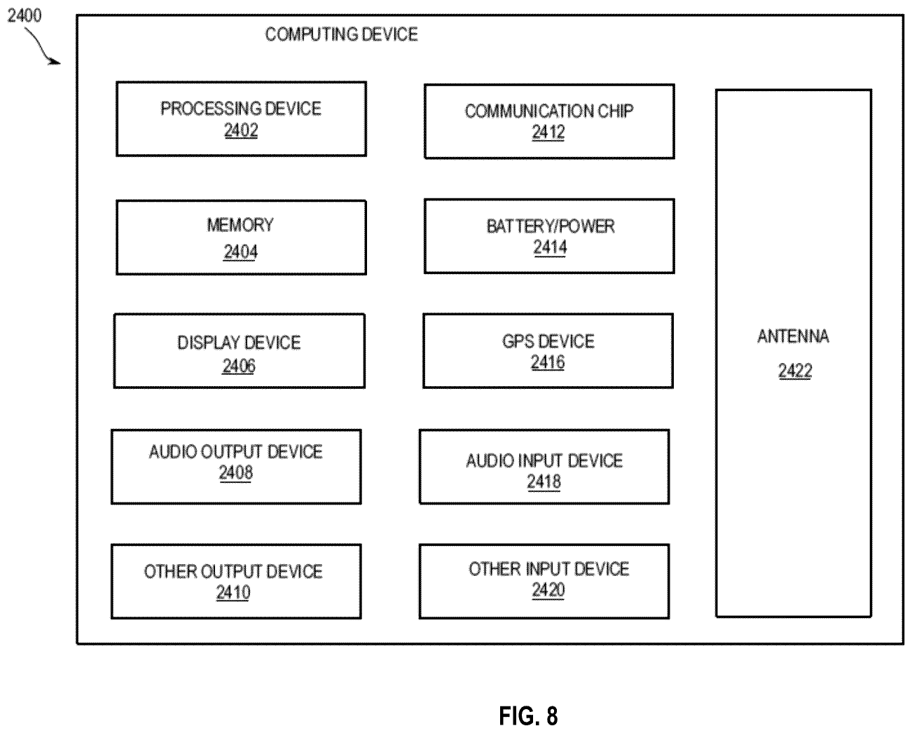

FIG. 8 is a block diagram of an example computing device 2400 that may include one or more components having one or more microelectronic assemblies 100 in accordance with any of the embodiments disclosed herein. For example, any suitable ones of the components of computing device 2400 may include a microelectronic assembly (e.g., 100) in accordance with any of the embodiments disclosed herein. In another example, any one or more of the components of computing device 2400 may include any embodiments of IC package 2200 (e.g., as shown in FIG. 6). In yet another example, any one or more of the components of computing device 2400 may include an IC device assembly 2300 (e.g., as shown in FIG. 7).

A number of components are illustrated in the figure as included in computing device 2400, but any one or more of these components may be omitted or duplicated, as suitable for the application. In some embodiments, some or all of the components included in computing device 2400 may be attached to one or more motherboards. In some embodiments, some or all of these components are fabricated onto a single SOC die.

Additionally, in various embodiments, computing device 2400 may not include one or more of the components illustrated in the figure, but computing device 2400 may include interface circuitry for coupling to the one or more components. For example, computing device 2400 may not include a display device 2406, but may include display device interface circuitry (e.g., a connector and driver circuitry) to which display device 2406 may be coupled. In another set of examples, computing device 2400 may not include an audio input device 2418 or an audio output device 2408, but may include audio input or output device interface circuitry (e.g., connectors and supporting circuitry) to which audio input device 2418 or audio output device 2408 may be coupled.

Computing device 2400 may include a processing device 2402(e.g., one or more processing devices). As used herein, the term “processing device” or “processor” may refer to any device or portion of a device that processes electronic data from registers and/or memory to transform that electronic data into other electronic data that may be stored in registers and/or memory. Processing device 2402 may include one or more DSPs, ASICs, CPUs, GPUs, cryptoprocessors (specialized processors that execute cryptographic algorithms within hardware), server processors, or any other suitable processing devices. Computing device 2400 may include a memory 2404, which may itself include one or more memory devices such as volatile memory (e.g., dynamic random access memory (DRAM)), nonvolatile memory (e.g., read-only memory (ROM)), flash memory, solid-state memory, and/or a hard drive. In some embodiments, memory 2404 may include memory that shares a die with processing device 2402. This memory may be used as cache memory and may include embedded dynamic random access memory (eDRAM) or spin transfer torque magnetic random access memory (STT-MRAM).

In some embodiments, computing device 2400 may include a communication chip 2412 (e.g., one or more communication chips). For example, communication chip 2412 may be configured for managing wireless communications for the transfer of data to and from computing device 2400. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 2412 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), LTE project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2412 may operate in accordance with a Global System for Mobile Communication (GSM), General Packet Radio Service (GPRS), Universal Mobile Telecommunications System (UMTS), High-Speed Packet Access (HSPA), Evolved HSPA (E-HSPA), or LTE network. The communication chip 2412 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 2412 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 2412 may operate in accordance with other wireless protocols in other embodiments. Computing device 2400 may include an antenna 2422 to facilitate wireless communications and/or to receive other wireless communications (such as AM or FM radio transmissions).

In some embodiments, communication chip 2412 may manage wired communications, such as electrical, optical, or any other suitable communication protocols (e.g., the Ethernet). As noted above, communication chip 2412 may include multiple communication chips. For instance, a first communication chip 2412 may be dedicated to shorter-range wireless communications such as Wi-Fi or Bluetooth, and a second communication chip 2412 may be dedicated to longer-range wireless communications such as global positioning system (GPS), EDGE, GPRS, CDMA, WiMAX, LTE, EV-DO, or others. In some embodiments, a first communication chip 2412 may be dedicated to wireless communications, and a second communication chip 2412 may be dedicated to wired communications.

Computing device 2400 may include battery/power circuitry 2414. Battery/power circuitry 2414 may include one or more energy storage devices (e.g., batteries or capacitors) and/or circuitry for coupling components of computing device 2400 to an energy source separate from computing device 2400 (e.g., AC line power).

Computing device 2400 may include a display device 2406 (or corresponding interface circuitry, as discussed above). Display device 2406 may include any visual indicators, such as a heads-up display, a computer monitor, a projector, a touchscreen display, a liquid crystal display (LCD), a light-emitting diode display, or a flat panel display, for example.

Computing device 2400 may include audio output device 2408 (or corresponding interface circuitry, as discussed above). Audio output device 2408 may include any device that generates an audible indicator, such as speakers, headsets, or earbuds, for example.

Computing device 2400 may include audio input device 2418 (or corresponding interface circuitry, as discussed above). Audio input device 2418 may include any device that generates a signal representative of a sound, such as microphones, microphone arrays, or digital instruments (e.g., instruments having a musical instrument digital interface (MIDI) output).

Computing device 2400 may include a GPS device 2416 (or corresponding interface circuitry, as discussed above). GPS device 2416 may be in communication with a satellite-based system and may receive a location of computing device 2400, as known in the art.

Computing device 2400 may include other output device 2410 (or corresponding interface circuitry, as discussed above). Examples of other output device 2410 may include an audio codec, a video codec, a printer, a wired or wireless transmitter for providing information to other devices, or an additional storage device.

Computing device 2400 may include other input device 2420 (or corresponding interface circuitry, as discussed above). Examples of other input device 2420 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 2400 may have any desired form factor, such as a handheld or mobile computing device (e.g., a cell phone, a smart phone, a mobile internet device, a music player, a tablet computer, a laptop computer, a netbook computer, an ultrabook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device. In some embodiments, computing device 2400 may be any other electronic device that processes data.

### Select Examples

The following paragraphs provide various examples of the embodiments disclosed herein.

Example 1 is a microelectronic assembly, including a first die in a first layer; and a second die and a third die in a second layer, the second layer coupled to the first layer by hybrid bond interconnects having a first bond pad and a second bond pad, where the first bond pad is coupled to a first via in the second die and the first bond pad is offset from the first via by a first dimension, and the second bond pad is coupled to a second via in the third die and the second bond pad is offset from the second via by a second dimension different than the first dimension.

Example 2 may include the subject matter of Example 1, and may further specify that the first bond pad is further offset from the first via in a first direction and the second bond pad is further offset from the second via in a second direction different than the first direction.

Example 3 may include the subject matter of Examples 1 or 2, and may further specify that the first bond pad has a first thickness, and wherein the hybrid bond interconnects further include a third bond pad having a second thickness different than the first thickness.

Example 4 may include the subject matter of any of Examples 1-3, and may further specify that the hybrid bond interconnects further include a third bond pad, and the microelectronic assembly and may further include a third via in the first die coupled to the third bond pad, wherein the third via is offset from the third bond pad by a third dimension different than the first dimension and the second dimension.

Example 5 may include the subject matter of any of Examples 1-4, and may further include a material around the second die and the third die in the second layer, the material including an inorganic dielectric.

Example 6 may include the subject matter of Example 5, and may further include a liner on and around the second die and the third die in the second layer between the material and the second die and the third die.

Example 7 may include the subject matter of Example 6, and may further specify that the liner has a thickness between 10 nanometers and 2 microns.

Example 8 may include the subject matter of any of Examples 1-7, and may further specify that the first via is at least partially within a cavity.

Example 9 may include the subject matter of any of Examples 1-8, and may further include an alignment mark.

Example 10 may include the subject matter of any of Examples 1-9, and may further include a substrate coupled to the first die in the first layer.

Example 11 may include the subject matter of any of Examples 1-9, and may further include an interposer coupled to the first die in the first layer; and a substrate coupled to the interposer.

Example 12 is a microelectronic assembly, including a first die in a first layer; and a second die and a third die in a second layer, the second layer coupled to the first layer by interconnects including a first bond pad and a second bond pad in a dielectric material, where the first bond pad is coupled to a first via in the second die and the first bond pad is offset from the first via in a first direction, and the second bond pad is coupled to a second via in the third die and the second bond pad is offset from the second via in a second direction different than the first direction.

Example 13 may include the subject matter of Example 12, and may further specify that the first bond pad is further offset from the first via by a first dimension and the second bond pad is further offset from the second via in a second dimension different than the first dimension.

Example 14 may include the subject matter of Examples 12 or 13, and may further specify that the first bond pad has a first thickness, and wherein the interconnects further include a third bond pad having a second thickness different than the first thickness.

Example 15 may include the subject matter of any of Examples 12-14, and may further include a material around the second die and the third die in the second layer, the material including an inorganic dielectric.

Example 16 may include the subject matter of Example 15, and may further include a liner on and around the second die and the third die in the second layer between the material and the second die and the third die, the liner including silicon and nitrogen, or silicon, carbon, and nitrogen.

Example 17 may include the subject matter of Example 16, and may further specify that the liner has a thickness between 10 nanometers and 2 microns.

Example 18 may include the subject matter of any of Examples 12-17, and may further specify that the first via is at least partially within a cavity.

Example 19 may include the subject matter of any of Examples 12-18, and may further include an alignment mark.

Example 20 may include the subject matter of any of Examples 12-19, and may further include a substrate coupled to the first die in the first layer.

Example 21 may include the subject matter of any of Examples 12-19, and may further include an interposer coupled to the first die in the first layer; and a substrate coupled to the interposer.

Example 22 is a microelectronic assembly, including a first die in a first layer; and a second die and a third die in a second layer, wherein the second layer is coupled to the first layer by first interconnects having a first thickness and by second interconnects having a second thickness different than the first thickness, wherein the first interconnects and the second interconnects have a pitch between 50 nanometers and 10 microns.

Example 23 may include the subject matter of Example 22, and may further include a material around the second die and the third die in the second layer, the material including an inorganic dielectric.

Example 24 may include the subject matter of Example 23, and may further include a liner on and around the second die and the third die in the second layer between the material and the second die and the third die.

Example 25 may include the subject matter of Example 24, and may further specify that the liner has a thickness between 10 nanometers and 2 microns.

Example 26 may include the subject matter of any of Examples 22-25, and may further include an alignment mark.

Example 27 may include the subject matter of any of Examples 22-26, and may further include a substrate coupled to the first die in the first layer.

Example 28 may include the subject matter of any of Examples 22-27, and may further include an interposer coupled to the first die in the first layer; and a substrate coupled to the interposer.

The above description of illustrated implementations of the disclosure, including what is described in the abstract, is not intended to be exhaustive or to limit the disclosure to the precise forms disclosed. While specific implementations of, and examples for, the disclosure are described herein for illustrative purposes, various equivalent modifications are possible within the scope of the disclosure, as those skilled in the relevant art will recognize.

1. A microelectronic assembly, comprising:
a first die in a first layer; and
a second die and a third die in a second layer, the second layer coupled to the first layer by hybrid bond interconnects having a first bond pad and a second bond pad,
wherein:
the first bond pad is coupled to a first via in the second die and the first bond pad is offset from the first via by a first dimension, and
the second bond pad is coupled to a second via in the third die and the second bond pad is offset from the second via by a second dimension different than the first dimension.

2. The microelectronic assembly of claim 1, wherein the first bond pad is further offset from the first via in a first direction and the second bond pad is further offset from the second via in a second direction different than the first direction.

3. The microelectronic assembly of claim 1, wherein the first bond pad has a first thickness, and wherein the hybrid bond interconnects further include a third bond pad having a second thickness different than the first thickness.

4. The microelectronic assembly of claim 1, wherein the hybrid bond interconnects further include a third bond pad, and the microelectronic assembly further comprising:
a third via in the first die coupled to the third bond pad, wherein the third via is offset from the third bond pad by a third dimension different than the first dimension and the second dimension.

5. The microelectronic assembly of claim 1, further comprising:
a material around the second die and the third die in the second layer, the material including an inorganic dielectric.

6. The microelectronic assembly of claim 5, further comprising:
a liner on and around the second die and the third die in the second layer between the material and the second die and the third die.

7. The microelectronic assembly of claim 6, wherein the liner has a thickness between 10 nanometers and 2 microns.

8. The microelectronic assembly of claim 1, wherein the first via is at least partially within a cavity.

9. The microelectronic assembly of claim 1, further comprising:
an alignment mark.

10. The microelectronic assembly of claim 1, further comprising:
a substrate coupled to the first die in the first layer.

11. The microelectronic assembly of claim 1, further comprising:
an interposer coupled to the first die in the first layer; and
a substrate coupled to the interposer.

12. A microelectronic assembly, comprising:
a first die in a first layer; and
a second die and a third die in a second layer, the second layer coupled to the first layer by interconnects including a first bond pad and a second bond pad in a dielectric material,
wherein:
the first bond pad is coupled to a first via in the second die and the first bond pad is offset from the first via in a first direction, and
the second bond pad is coupled to a second via in the third die and the second bond pad is offset from the second via in a second direction different than the first direction.

13. The microelectronic assembly of claim 12, wherein the first bond pad is further offset from the first via by a first dimension and the second bond pad is further offset from the second via in a second dimension different than the first dimension.

14. The microelectronic assembly of claim 12, wherein the first bond pad has a first thickness, and wherein the interconnects further include a third bond pad having a second thickness different than the first thickness.

15. The microelectronic assembly of claim 12, wherein the first via is at least partially within a cavity.

16. A microelectronic assembly, comprising:
a first die in a first layer; and
a second die and a third die in a second layer, wherein the second layer is coupled to the first layer by first interconnects having a first thickness and by second interconnects having a second thickness different than the first thickness, wherein the first interconnects and the second interconnects have a pitch between 50 nanometers and 10 microns.

17. The microelectronic assembly of claim 16, further comprising:
a material around the second die and the third die in the second layer, the material including an inorganic dielectric.

18. The microelectronic assembly of claim 17, further comprising:
a liner on and around the second die and the third die in the second layer between the material and the second die and the third die.

19. The microelectronic assembly of claim 18, wherein the liner has a thickness between 10 nanometers and 2 microns.

20. The microelectronic assembly of claim 16, further comprising:
an alignment mark.
